(19) United States
(12) Patent Application Publication
(10) Pub. No.: US 2021/0194459 A1
(43) Pub. Date: Jun. 24, 2021

(54) BROADBAND ACOUSTIC WAVE RESONATOR (AWR) FILTERS

(71) Applicant: Intel Corporation, Santa Clara, CA (US)

(72) Inventors: Hossein Alavi, Portland, OR (US); Ibrahim Ban, Beaverton, OR (US); Telesphor Kamgaing, Chandler, AZ (US); Edris Mohammed, Beaverton, OR (US); Han Wui Then, Portland, OR (US); Kevin Obrien, Portland, OR (US); Paul Fischer, Portland, OR (US); Johanny Escobar Pelaez, Zapopan (MX); Ved Gund, Hillsboro, OR (US)

(21) Appl. No.: 16/719,077

(22) Filed: Dec. 18, 2019

(51) Int. Cl. H03H 9/54; H03H 9/64; H03H 9/25; H03H 9/58; H03H 9/205

(52) U.S. Cl. CPC H03H 9/542; H03H 9/6403; H03H 9/25; H03H 9/6406; H03H 9/584; H03H 9/205; H03H 9/547

(57) ABSTRACT

Techniques are disclosed implementing acoustic wave resonator (AWR) filter architectures to enable integrated solutions requiring significantly less passive components. The primary AWR filter topology leverages the use of parallel resonator branches, each having a relatively narrow bandwidth that may be combined to form an overall broadband filter response. This architecture may be further modified using electronically-controlled switching components to dynamically turn specific branches on or off to tune the filter, thus realizing a programmable broadband solution. Shunt resonators may also be added to the AWR filter topology, which may also be controlled with the use of electronically-controlled switching components to provide further control with respect to roll-off and the location and number of notch frequencies.

### TECHNICAL FIELD

Aspects described herein generally relate to filters and, more particularly, to broadband acoustic wave resonator (AWR) filters.

### BACKGROUND

Front-end module (FEM) filtering functions as the first line of defense in protecting communication systems and networks against the barrage of unwanted signals (interference) and ambient noise. Acoustic wave resonators (AWR) such as micro-electromechanical systems MEMS resonators include surface acoustic wave (SAW) resonators, bulk acoustic wave (BAW) resonators, thin-film bulk acoustic resonators (FBAR), etc. Such resonators form the base building blocks of FEM filters, as AWRs are unrivalled with respect to meeting the stringent insertion loss, sharpness, and form-factor filtering requirements required for many applications such as mobile devices. Traditional AWR filters, however, suffer from bandwidth limitations, and thus fall short of meeting anticipated bandwidth requirements for new mobile device technologies.

### BRIEF DESCRIPTION OF THE DRAWINGS/FIGURES

The accompanying drawings, which are incorporated herein and form a part of the specification, illustrate the aspects of the present disclosure and, together with the description, and further serve to explain the principles of the aspects and to enable a person skilled in the pertinent art to make and use the aspects.

FIG. 1 illustrates a graph of a typical impedance response of an acoustic wave resonator (AWR) filter.

FIG. 2 illustrates a schematic of a typical acoustic wave lumped resonator (AWLR) filter architecture.

FIGS. 3A-3B illustrate schematics of kₜ² agnostic broadband AWR filter architectures.

FIG. 4 illustrates a schematic diagram of an exemplary modular multi-branch AWR filter architecture, in accordance with an aspect of the disclosure.

FIG. 5 illustrates a graph of an exemplary filter response for a single AWR filter branch, in accordance with an aspect of the disclosure.

FIG. 6 illustrates a graph of the filter response for the multi-branch AWR filter architecture as shown in FIG. 4 having three resonator branches, in accordance with an aspect of the disclosure.

FIG. 7 illustrates a schematic diagram of an exemplary programmable modular multi-branch AWR filter architecture with switchable resonator branches, in accordance with an aspect of the disclosure.

FIGS. 8A-1, 8A-2, 8B-1, 8B-2, 8C-1, 8C-2, 8D-1, and 8D-2 illustrate graphs of exemplary filter responses for the programmable modular AWR filter architecture as shown in FIG. 7 having five resonator branches with different tuning configurations, in accordance with an aspect of the disclosure.

FIG. 9 illustrates a schematic diagram of an exemplary programmable modular multi-branch AWR filter architecture with switchable resonator branches and switchable shunt resonators, in accordance with an aspect of the disclosure.

FIGS. 10A-10B illustrates graphs of exemplary filter responses for the programmable modular AWR filter architecture as shown in FIG. 9 having four resonator branches and two shunt resonators in a specific tuning configuration, in accordance with an aspect of the disclosure.

FIG. 11 illustrates device, in accordance with an aspect of the disclosure.

FIG. 12A illustrates a typical 2-port MEMS structure.

FIG. 12B illustrates details of the 2-port MEMS structure shown in FIG. 12A indicating width and length design parameters.

FIG. 13A illustrates a table showing classic Butterworth polynomial values.

FIG. 13B illustrates a table showing classic Chebyshev polynomial values.

FIG. 14 illustrates a non-uniformly coupled resonator array, in accordance with an aspect of the disclosure.

The exemplary aspects of the present disclosure will be described with reference to the accompanying drawings. The drawing in which an element first appears is typically indicated by the leftmost digit(s) in the corresponding reference number.

### DETAILED DESCRIPTION

In the following description, numerous specific details are set forth in order to provide a thorough understanding of the aspects of the present disclosure. However, it will be apparent to those skilled in the art that the aspects, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

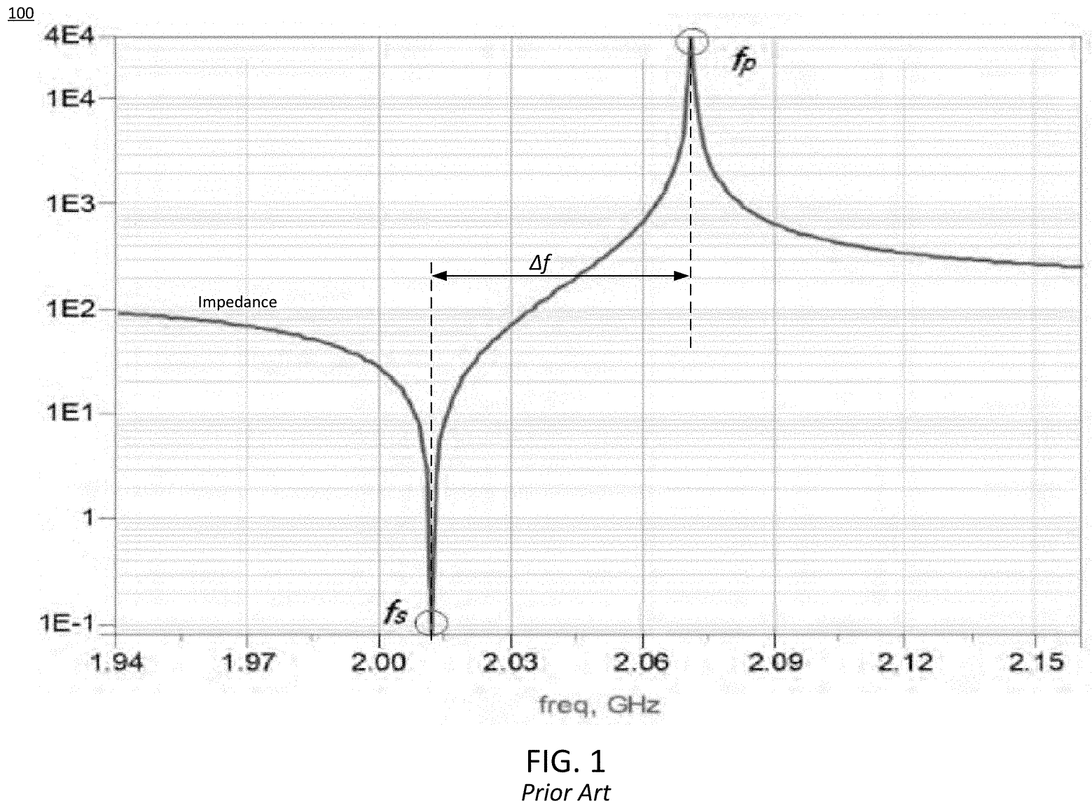

Again, traditional AWR filters suffer from bandwidth limitations. This shortcoming stems from what is referred to as “anti-resonance,” or a parallel resonant frequency that is observed in the frequency spectrum close to the resonant (i.e. the series resonant) frequency in MEMS resonators. With reference to FIG. 1, which illustrates a graph of a typical impedance response for a MEMS resonator over a frequency band as shown, the parallel resonant frequency is denoted as fₚ, and the MEMS resonator frequency, i.e. the series resonant frequency, is depicted as fₛ. Thus, as shown in FIG. 1, this “double resonance” property limits the traditional bandpass operation of MEMS resonators to the small bandwidth between resonance and anti-resonance, denoted in FIG. 1 as Δf=fₚ−fₛ. This phenomenon is related to what is referred to as the “electro-mechanical transduction” or “electro-mechanical coupling” coefficient kₜ² of the MEMS resonator, which may be expressed in Equation 1 below as:

$${k}_{t}^{2} = \frac{{π}^{2}}{8} \frac{{f}_{p}^{2} - {f}_{s}^{2}}{{f}_{p}^{2}} \approx \frac{{π}^{2}}{4} \frac{Δ f}{{f}_{p}} \qquad Eqn . 1$$

The value of kₜ² in MEMS resonators is highly dependent on the type of piezoelectric material used, and typically ranges from between ˜0.1% (or 0.001) to ˜7% (or 0.07) for industry standard materials such as Lead Zirconate Titanate (PZT), Aluminum Nitride (AlN), Zinc Oxide (ZnO), etc. Other factors, such as resonator type and physical structure, metal electrode shape and thickness, and filter structure also play significant roles in the achievable filter bandwidth (BW). As shown below in Equation 2 below, the effective electro-mechanical coupling coefficient k_{eff}² represents an effective electro-acoustic coefficient, taking all such effects into account to represent an overall coupling coefficient for a particular MEMS resonator filter. The value of k_{eff}² in MEMS resonator filters thus influences the overall fractional bandwidth (FBW) in such systems, which is defined below in Equation 2 as follows:

$$FBW = \frac{BW}{{f}_{s}} \approx \frac{4}{{π}^{2}} {k}_{eff}^{2} \approx 0.4 {k}_{eff}^{2} \qquad Eqn . 2$$

Some attempts to address the current MEMS bandwidth limitations have been directed to providing specific crystal shapes (i.e. cuts), and combining these with exotic materials such as Lithium Niobate or Lithium Tantalite. Such solutions have been shown to achieve a coupling coefficient in the range of 30-40% or more. However, thin film deposition of these materials, which is essentially required for modern day large-scale manufacturing processes, are not yet possible, as such solutions current exist primarily in expensive bulk crystal form. Moreover, these materials are not suited for integrated solutions, which again is needed to address large-scale device manufacturing.

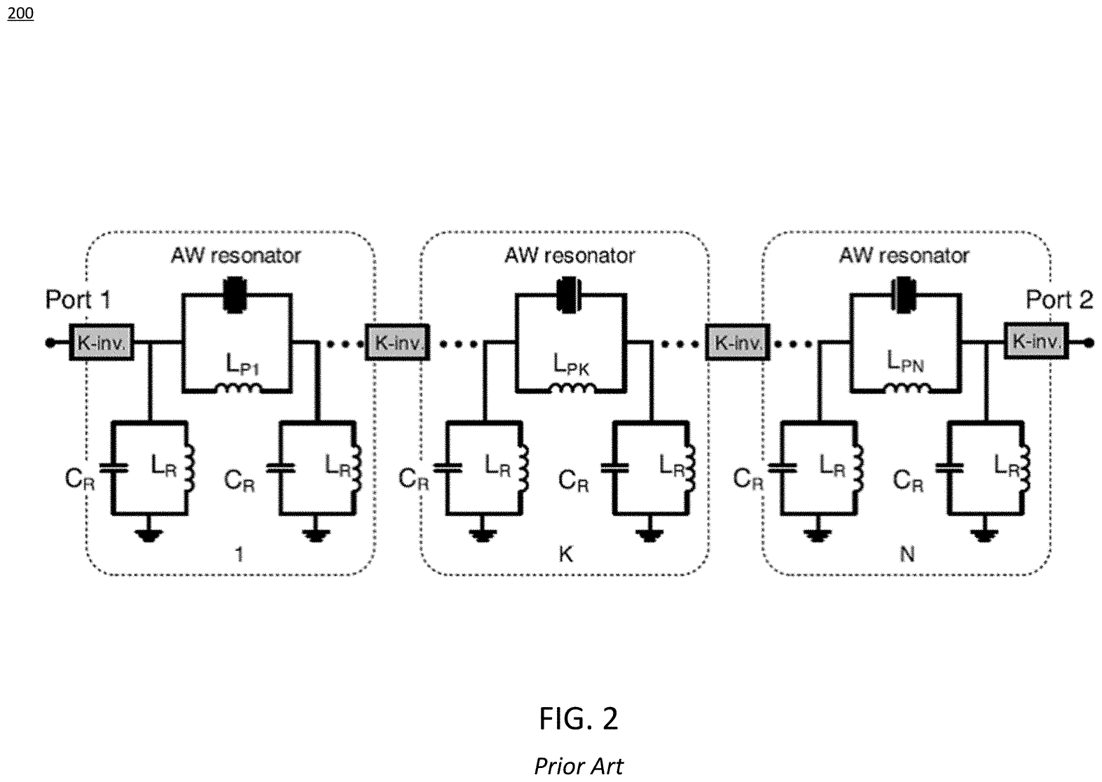

Other attempts to address MEMS resonator bandwidth limitations include the use of an acoustic wave lumped resonator (AWLR) architecture, as shown in FIG. 2. The AWLR architecture 200 implements an array of single port acoustic resonators in parallel with an inductor, which functions to cancel out the parallel electro-static capacitance, thereby eliminating the anti-resonance. The parallel inductor+resonator pairs are coupled to one another via K-inverters as shown. This topology also adds shunt LC resonators between the K-inverter-coupled AW resonators to manage out-of-band rejection. Such AWLR architectures claim to enhance the value of k_{eff}² by 5 times.

However, for AWLR topologies, the signal traveling through the parallel LC branch in each AW resonator interacts with the in series K-inverters and, due to phase mismatch, creates an interference pattern resulting in a new spectral notch. Although this notch is further out (spectrally) than the cancelled anti-resonance discussed above with reference to FIG. 1, this nonetheless still limits the achievable bandwidth to about 5 times the typical MEMS resonator bandwidth. Moreover, the AWLR topology requires the use of several additional passive components and thus results in a large form-factor, making such a solution impractical for smaller, integrated solutions used for mobile devices. Furthermore, AWLR architectures suffer from relatively large losses, which impact achievable insertion loss and return loss and, in turn, the rejection level.

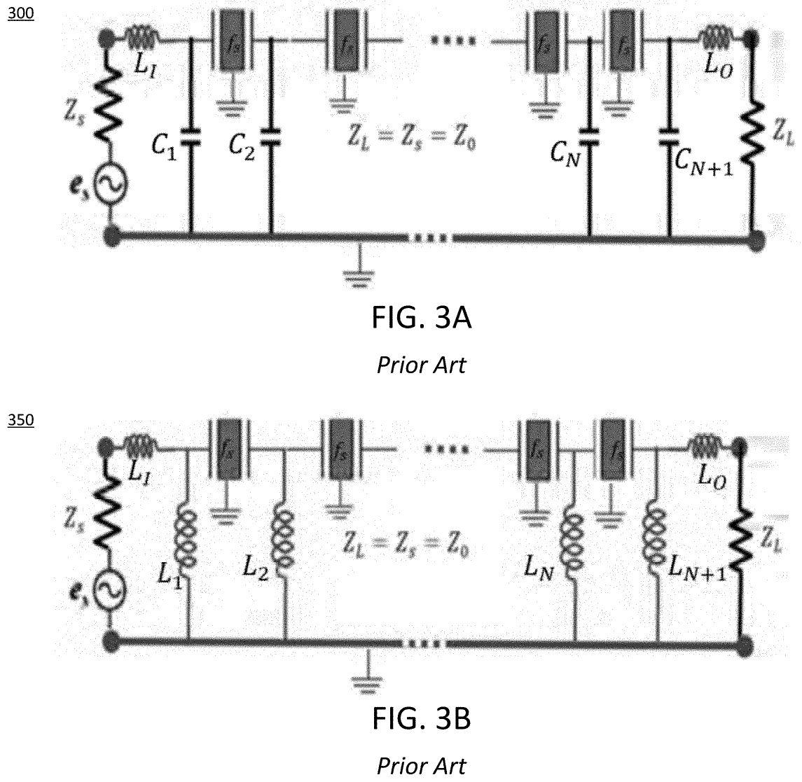

Another solution to address the MEMS resonator bandwidth limitations as noted above includes the use of what is referred to as a reactively-coupled cascaded 2-port resonator array, which may be alternatively referred to as a kₜ² agnostic broadband AWR filter. Examples of two different types of kₜ² agnostic broadband AWR filters 300, 350 are shown in FIGS. 3A-3B, respectively.

As shown in FIGS. 3A-3B, the id agnostic broadband AWR filter may be implemented using 2-port (3-terminal) resonators coupled through shunt reactive components such as capacitors (FIG. 3A) or inductors (FIG. 3B). Such an architecture provides an effective wideband solution independent of the resonators' k_{eff}² . However, although the acoustic resonators themselves may be formed as part of an integrated design, such kₜ² agnostic broadband AWR filter implementations still require the use of external passive components coupled between the resonators. As a result, these solutions are not easily reconfigurable, as the filter response of the AWR filter is dependent upon the reactive values associated with these external passives, nor do these designs lend themselves well to fully integrated solutions.

Therefore, to address these issues, the aspects described herein implement various approaches for AWR filter implementation, which allows for integrated solutions requiring significantly less passive components. The primary AWR filter topology further discussed herein leverages the use of parallel branches of directly cascaded 2-port resonators, each having a relatively narrow bandwidth, which may be combined together to form an overall broadband filter response. As discussed in further detail below, this architecture may be further modified using electronically-controlled switching components to dynamically turn specific resonator branches on or off to tune the filter, thus realizing a digitally programmable broadband solution. Shunt resonators may also be added to the AWR filter topology, which may also be controlled with the use of electronically-controlled switching components to provide further control with respect to roll-off and the location, depth, and number of notches.

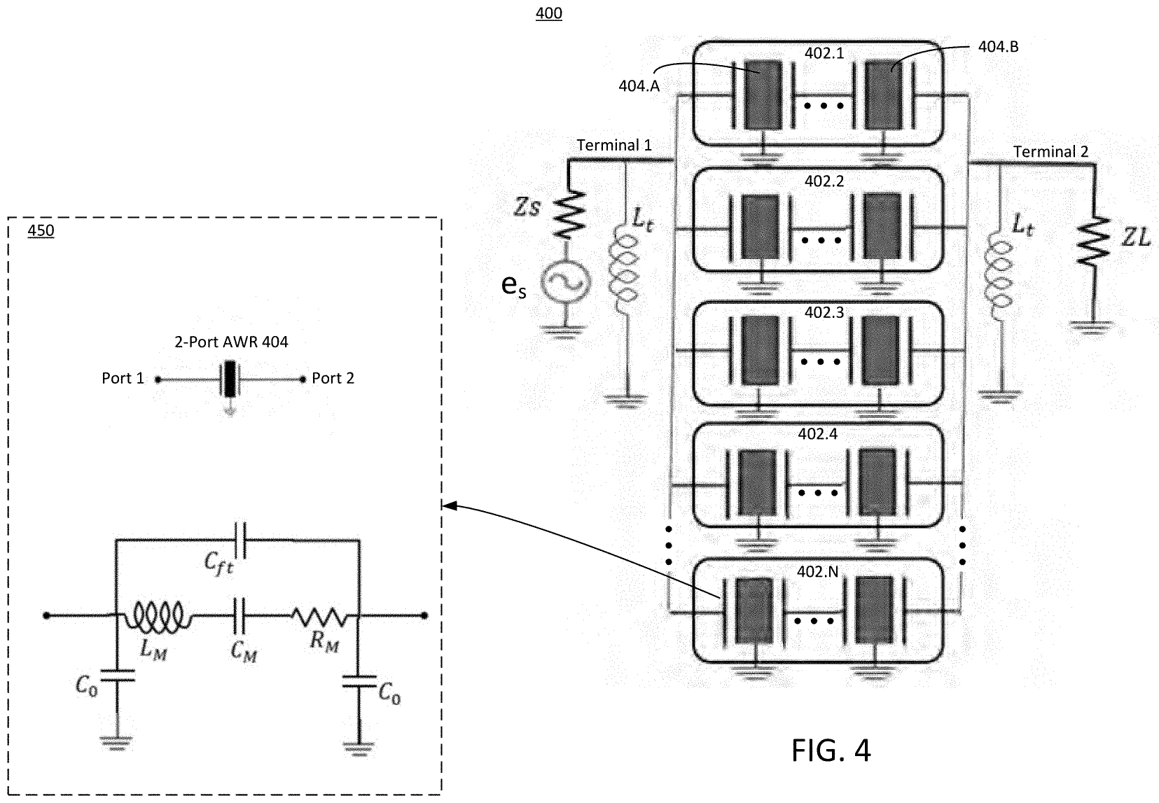

FIG. 4 illustrates a schematic diagram of an exemplary modular multi-branch AWR filter architecture, in accordance with an aspect of the disclosure. The AWR filter 400 may be implemented as part of any suitable type of device or application in which signal filtering is utilized. For example, the AWR filter 400 may be placed between an amplifier and antenna as part of a receive or a transmit chain implemented as part of a wireless device. Thus, the source eₛ and corresponding source impedance Z_{S} as shown in FIG. 4 may be associated with the input of the AWR filter 400, and represent any suitable source of time-varying electromagnetic signals associated with a particular implementation of the AWR filter 400 (e.g. a power amplifier output in a transmit chain or an antenna port in a receive chain). Moreover, the load impedance Z_{L} as shown in FIG. 4 may be associated with the output of the AWR filter 400 and represent the impedance of the load of a particular component based upon the particular implementation of the AWR filter 400 (e.g. an antenna impedance in a transmit chain or a low-noise amplifier (LNA) impedance in a receive chain). The pair of matching inductors Lₜ as shown may be of any suitable type, which are used to facilitate impedance matching between the input and output ports and may have values selected using known impedance matching techniques.

The aspects described herein implement 2-port acoustic wave resonators (AWRs) in various types of topologies to combine the narrow band responses from several AWR resonator branches 402.1-402.N to realize a broadband and/or multi-band filter response. To do so, the AWR filter 400 may include any suitable number N of 2-port resonator branches 402.1-402.N, with 5 resonator branches being shown in the example shown in FIG. 4 (i.e. N=5). For instance, in an aspect, each resonator branch 402.1-402.N of the AWR filter 400 may include any suitable number of AWRs 404, which are coupled in series with one another. For brevity and ease of explanation, the example aspects discussed herein implement two AWRs 404.A, 404.B per resonator branch 402, although this is by way of example and not limitation, and the aspects described herein may include any suitable number of AWRs 404 coupled in series with one another. Furthermore, each resonator branch 402 is shown in FIG. 4 having the same number of AWRs 404 (i.e., 2), which is also by way of example and not limitation. In fact, each resonator branch 402.1-402.N may include the same number of AWRs 404 or a different number, in various aspects.

An example AWR 404, which includes two ports, is represented by the schematic symbol as shown in the inset 450 in FIG. 4. However, the aspects described herein not limited to AWRs having any specific number of ports, and AWRs having any suitable number of ports may be implemented. In various aspects, the AWRs 404 may also be implemented as any suitable type of resonating medium and/or structure to facilitate resonance in accordance with any suitable frequency or band of frequencies. Continuing the example as shown in the inset 450 of FIG. 4, each AWR 404 of the AWR filter 400 may include two ports and three terminals, which include an input port (e.g. port 1), an output port (e.g. port 2), and a ground, which are each coupled to or otherwise form a respective electrode or terminal. The two ports of the AWR 404 thus interact with one another through a suitable medium, such as a piezo-electric medium, for example. The example AWR 404 may be implemented as a micro-electromechanical system (MEMS) resonator and, in the case when a piezo-electric medium is used, may specifically be implemented as a piezo-MEMS resonator. Such implementations are advantageous in that piezo-MEMS resonators are widely available, have lower costs, and are better understood based upon their history of use in AWR filters than MEMS resonators implementing more exotic materials as discussed above.

Moreover, as shown in FIG. 4 using the example of two AWRs 404.A, 404B, each of the resonator branches 402.1-402.N may be coupled in parallel with one another such that the same respective port (e.g., port 1) of each AWR corresponding to AWR 404.A within each resonator branch 402.1-402.N is coupled to one another and to a first terminal (e.g. terminal 1) of the AWR filter 400. Furthermore, the same respective port (e.g., port 2) of each AWR 404 corresponding to AWR 404.B within each resonator branch may be coupled to one another and to a second terminal (e.g. terminal 2) of the AWR filter 400. Again, each resonator branch 402.1-402.N includes any suitable number of AWRs 404 coupled in series with one another, with an output port (e.g. port 2) of one AWR 404 being connected to an input port (e.g. port 1) of the next connected AWR 404 in the resonant branch. Using the example of two AWRs 404A, 404B as shown in FIG. 4 as an example, the AWRs 404.A, 404.B within the resonant branch 402.1 are coupled to one another in series such that port 2 of the AWR 404.A is coupled to port 1 of the AWR 404.B. Advantageously, each AWR 404 may be coupled directly to one another without the use of additional passives such that the intrinsic inductance and capacitance associated with each AWR as shown in the Butterworth-Van Dyke (BVD) circuit model in the inset 450 is used as part of the filter coefficient calculations, as further discussed in the Appendix.

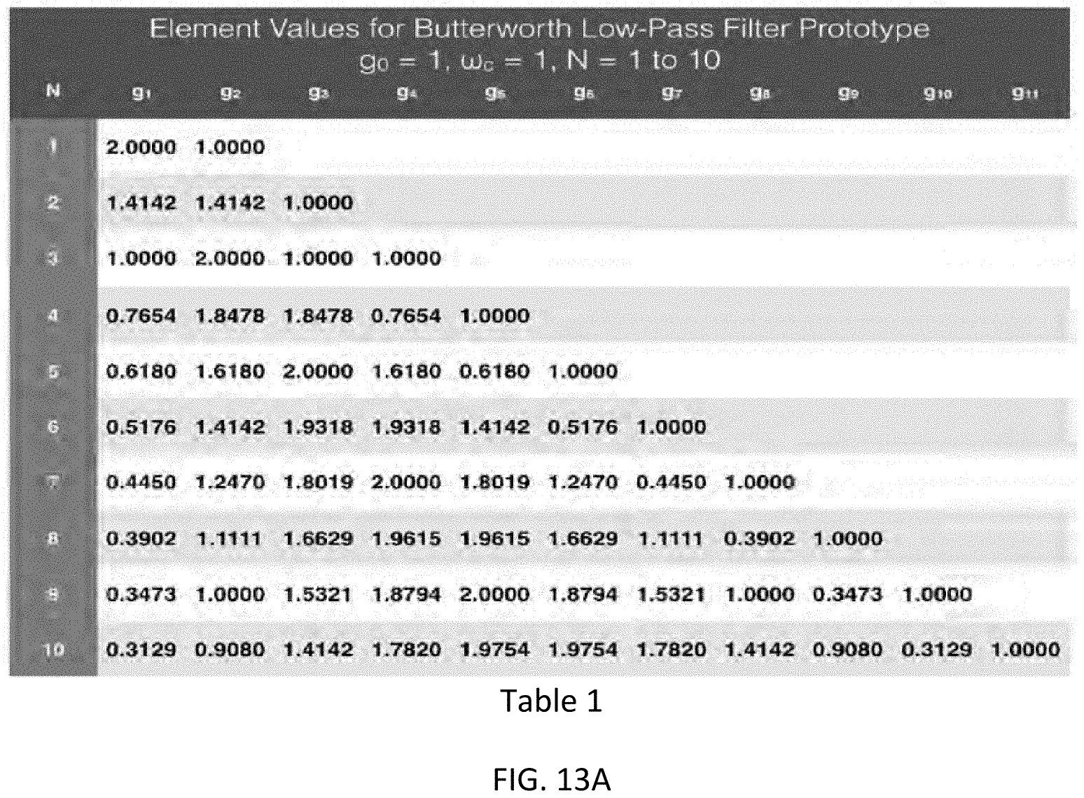

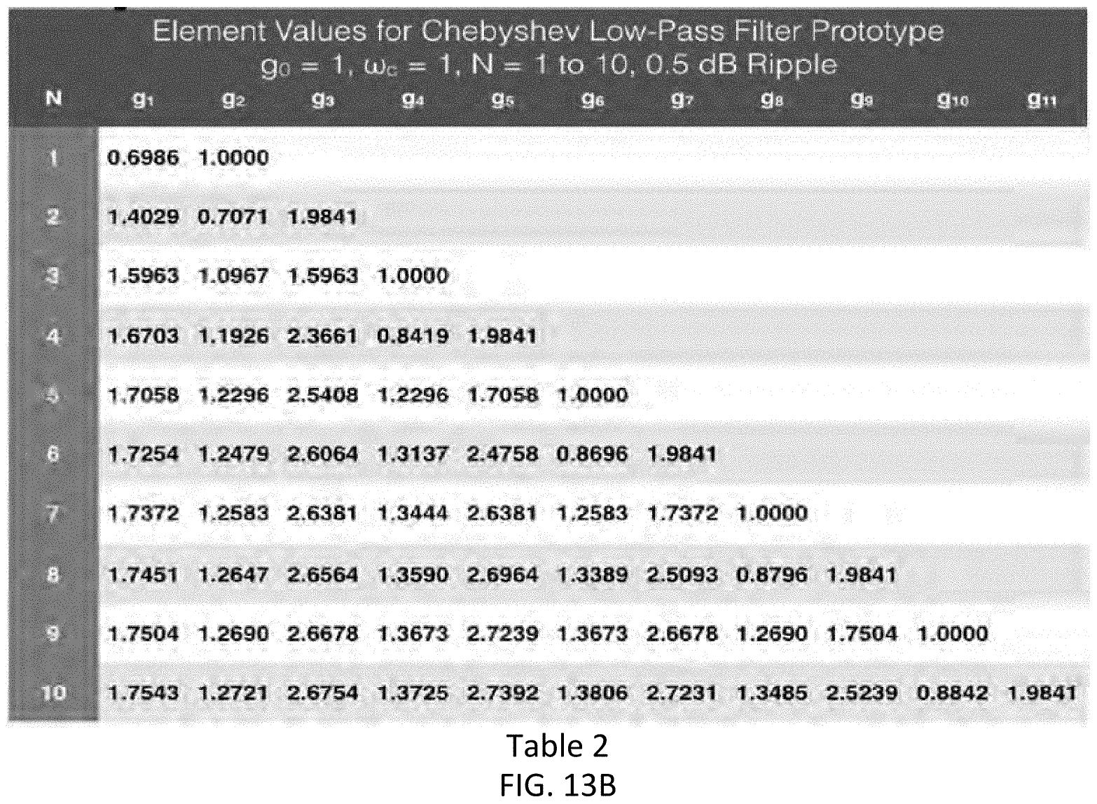

The AWRs 404 of each different resonator branch 402.1-402.N of the AWR filter 400 are referred to herein collectively as the AWRs 404 associated with the AWR filter 400. However, it should be noted that although the AWRs 404 implemented in the AWR 400 may be of the same AWR type and topology (e.g. each AWR 404 may be a two-port, three-terminal piezo MEMS resonator), each AWR 404 and in particular each AWR 404 coupling within each resonator branch 402.1-402.N (e.g. the series-coupled AWRs 404A, 404B), may be tuned to resonate at a different frequency and/or band of frequencies. In other words, the AWRs 404 may each have a similar resonator structure but not be identical. For clarity, the design, manufacturing, and tuning process for the AWRs 404 alone and when coupled in series to form the individual resonator branches 402 is discussed with reference to the Appendix, the inset 450, as well as FIGS. 4, 12A-12B, and 13A-13B.

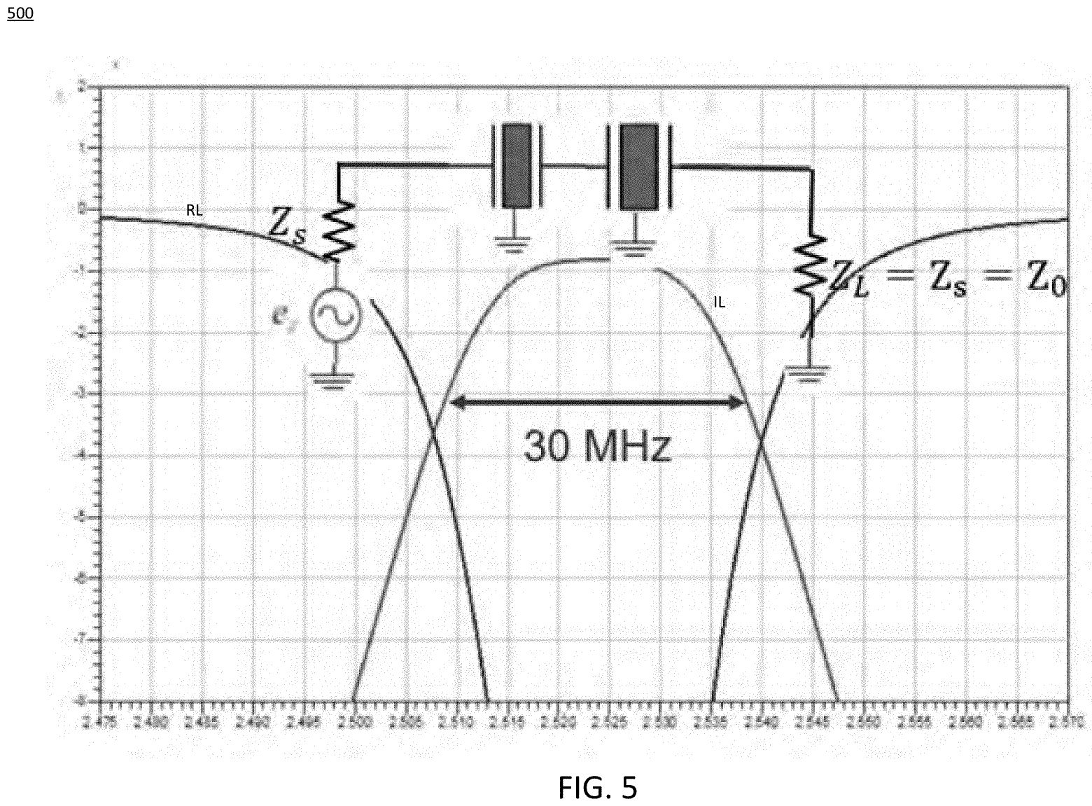

Regardless of the manner in which the AWRs 404 and the resonator branches 402.1-402.N are tuned, aspects include each of the resonator branches 402.1-402.N providing a different filter response with respect to one another. Using a bandpass filter response as an example, the aspects include each of the resonator branches 402.1-402.N providing a different bandpass frequency response, i.e. a different passband frequency. Each of these different bandpass responses is relatively narrow-banded, as each resonator branch 402 individually has a bandpass bandwidth proportional to the k_{eff}² of the AWRs 404 within each respective resonator branch 402.1-402.N. For example, FIG. 5 illustrates an exemplary filter response for a single resonator branch 402. In other words, the graph 500 shows a passband filter response for the AWR filter 400 as shown in FIG. 4 having a single resonator branch 402 that includes the two AWRs 404.A, 404.B. In this example, the single resonator branch 402 has a kₜ² value of approximately 1.2%, and thus provides a passband of about 30 MHz centered about 2.5 GHz in this example.

The aspects described herein thus advantageously leverage the multi-branch architecture of the AWR filter 400 to constructively combine the narrow-band responses of each of the constituent resonator branches 402 to produce a broadband spectral response. In other words, the aspects allow each resonator branch 402 to effectively quantize a desired bandwidth that forms a different portion of the overall filter response of the AWR filter 400, i.e. the operational passband of the AWR filter 400.

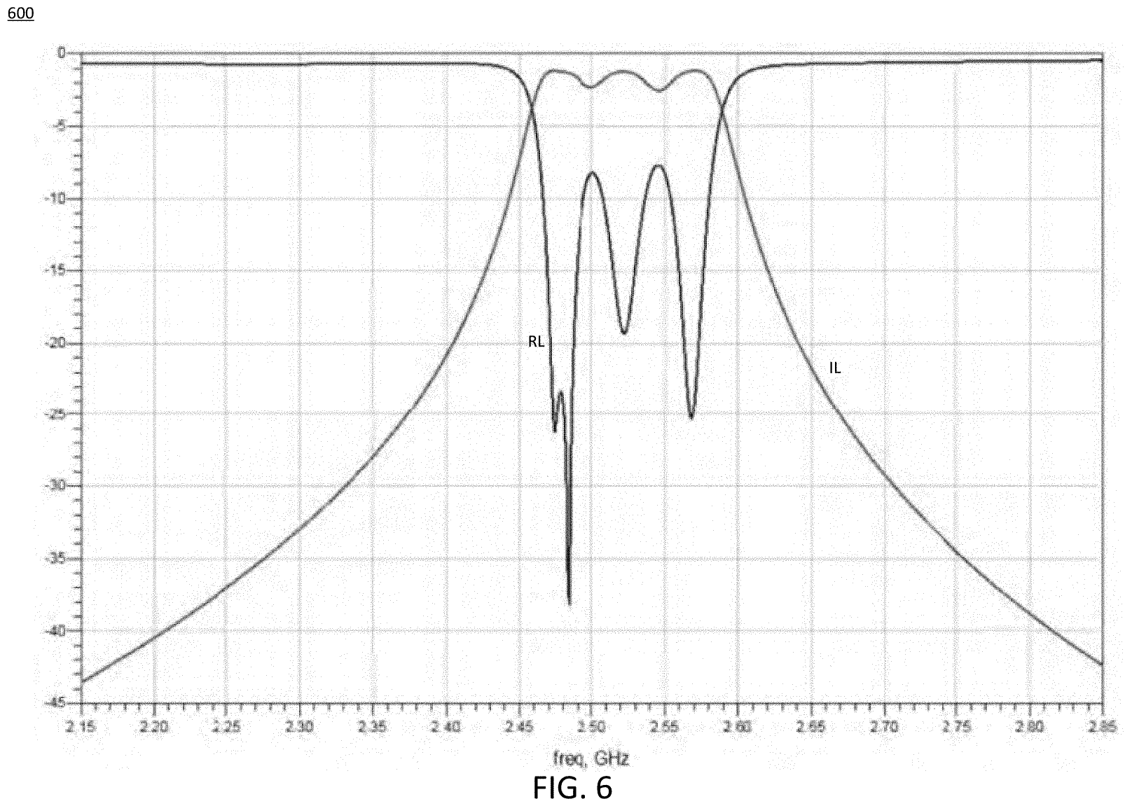

For example, FIG. 6 illustrates an exemplary filter response for three resonator branches 402.1-402.3. In other words, the graph 600 shows a passband filter response for the AWR filter 400 as shown in FIG. 4 having three resonator branches 402.1-402.3, each including two AWRs 404.A, 404.B. In this example, each single resonator branch 402 has a kₜ² value of approximately 1.2%, and the matching inductors Lₜ have a value of 1.7 nH. As can be seen from FIG. 6, the combination of three resonator branches 402.1-402.3 increases the passband to 130 MHz.

And as each resonator branch 402 uses only coupled two-port acoustic resonators without additional passive components (no inductors or capacitors), the multiple resonator branches 402.1-402.N of the AWR filter 400 may also advantageously be implemented as an integrated design, such as a single integrated chip for instance. For example, each of the resonant branches 402.1-402.N may be formed as part of a single integrated solution terminated as terminals 1 and 2 as shown in FIG. 4 such that the AWD filter 400 may be implemented as part of a practical wireless communication system. Of course, as in any RF filtering solution, the pair of matching inductors Lₜ is typically (but not necessarily) required for I/O matching, as discussed above.

Although the example aspects as discussed herein are provided with respect to bandpass filters, the aspects are not limited to these filter types, and the aspects described herein may provide any suitable frequency response with respect to filter response shape and/or other filter parameters such as notch locations, passbands, stopbands, etc. Moreover, and as noted above, RF filtering solutions typically implement matching inductors Lₜ for I/O matching. The AWR filter 400 may optionally include other external passive components based upon space considerations and/or the desired frequency response characteristics. For instance, one or more inductors or capacitors may be coupled between the first and second terminals of the AWR filter 400 (i.e. not shown, but parallel with each of the resonator branches 402) having any suitable values to provide sharper frequency roll-offs, if desired.

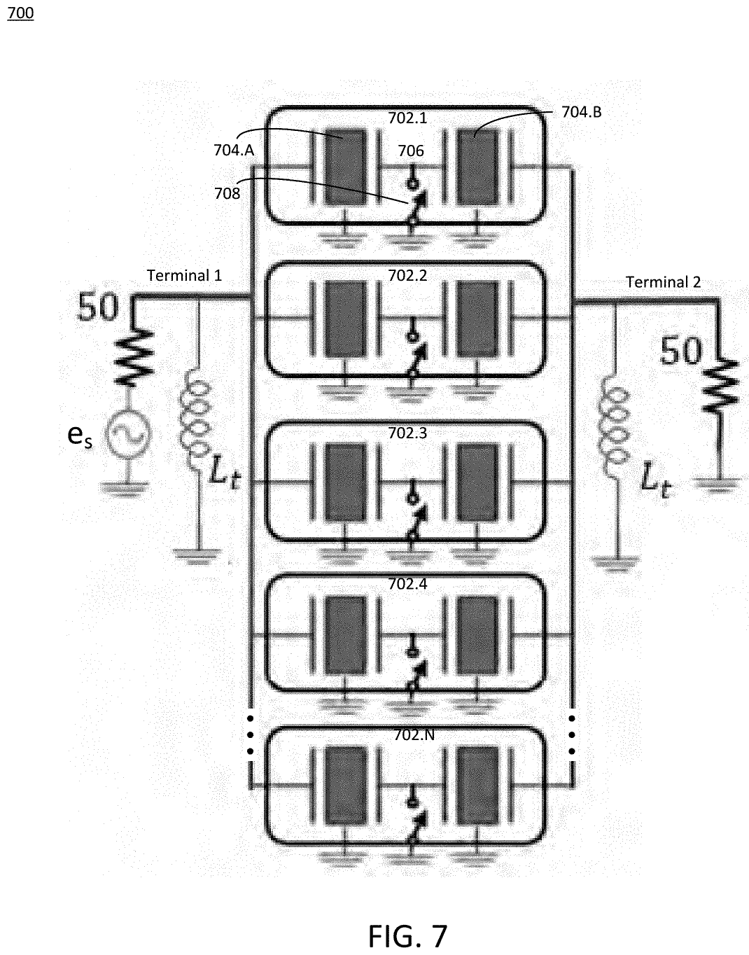

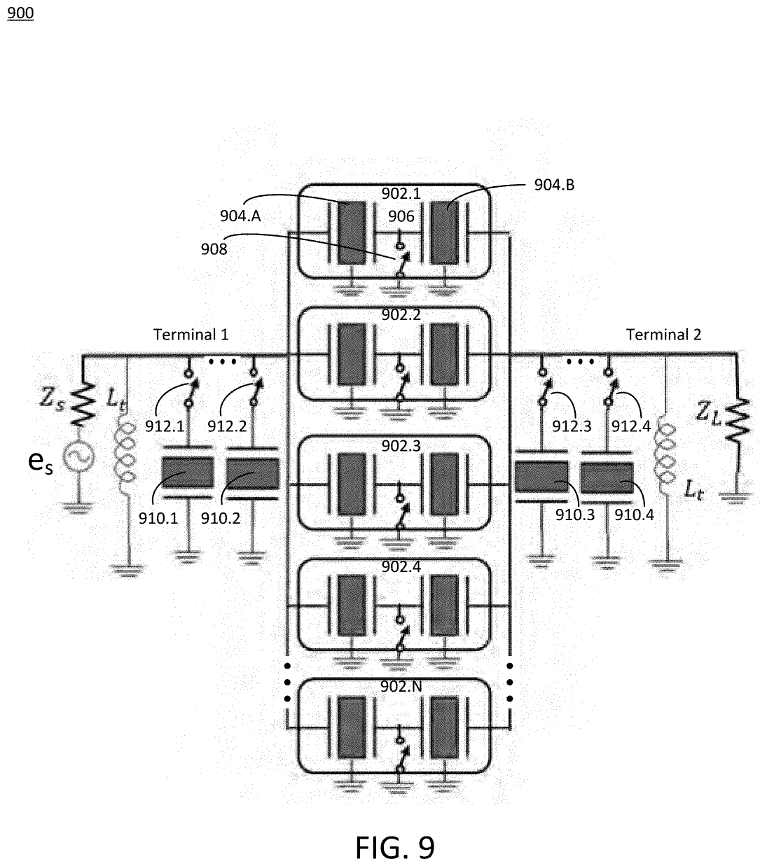

Again, aspects of the AWR filter 400 include quantizing the relatively narrow passbands of several resonator branches 402.1-402.N to provide an overall broadband frequency response, as can be seen by comparing FIGS. 5 and 6. However, the frequency response of the AWR filter 400 is fixed or static in nature. In other words, the overall frequency response of the AWR filter 400 is based upon the frequency response of each resonator branch 402.1-402.N that is combined, and thus any desired changes to the overall frequency response would require one or more of the resonator branches 402.1-402.N to be re-tuned or, alternatively, one or more of the resonator branches 402.1-402.N to be removed or disconnected. This may be an acceptable solution for some applications in which there are not anticipated changes in the required filter response. However, for other applications (e.g., mobile phones designed to be used in different international operating regions with different filter response requirements), it may be desirable to have the ability to dynamically adjust the characteristics of the AWR filter's response. Therefore, the following aspects discussed below with respect to the AWR filter topologies as shown in FIGS. 7 and 9 address these concerns using a programmable filter design.

FIG. 7 illustrates a schematic diagram of an exemplary programmable modular multi-branch AWR filter architecture with switchable resonator branches, in accordance with an aspect of the disclosure. The programmable AWR filter 700 may be digitally programmable and include similar or identical components as the AWR filter 400 as shown and discussed herein with reference to FIG. 4; therefore, only differences between the AWR filters 400, 700 will be further discussed herein for purposes of brevity.

For instance, like the AWR filter 400, the AWR filter 700 also includes a source eₛ and corresponding source impedance Z_{S}, which may be associated with the input of the AWR filter 700 and represent any suitable source of time-varying electromagnetic signals. Furthermore, the AWR filter 700 also includes a load impedance Z_{L} that is associated with the output of the AWR filter 700 representing the impedance of the load of a particular component based upon the particular implementation of the AWR filter 700, and matching inductors Lₜ. For ease of explanation, the source impedance Z_{S} and the load impedance Z_{L} are each assumed to be 50 Ohms in this example.

Moreover, like the AWR filter 400, the AWR filter 700 also includes any suitable number of resonator branches 702.1-702.N connected in parallel with one another. The resonator branches 702.1-702.N may be arranged and implemented in a substantially similar or identical manner as the resonator branches 402.1-402.N as shown and described above with reference to the AWR Filter 400 as shown in FIG. 4. Thus, aspects include each resonator branch 702.1-702.N also including any suitable number of AWRs 704, such as the two AWRs 704.A, 704.B as shown in FIG. 7 with respect to the resonator branch 702.1. Again, the AWRs 704 may be implemented as any suitable type of acoustic wave resonator (e.g. a 2-port AWR), such as the piezo-MEMS resonators discussed herein.

As discussed above for the AWR filter 400, each resonator branch 702.1-702.N also uses only coupled two-port acoustic resonators without additional passive components (no inductors or capacitors). Therefore, each of the resonant branches 702.1-702.N may also advantageously be implemented as an integrated design, such as a single integrated chip for instance.

However, the AWR filter 700 differs from the AWR filter 400 in that each of the resonator branches 702.1-702.N is configured to be selectively and independently controlled with respect to its own resonant state. In other words, the filter response associated with the AWR filter 700 may be a result of any selected combination of one or more of the resonant branches 702.1-702.N. To do so, each of the resonator branches 702.1-702.N may include a set of respective AWRs 704 that are coupled in series with one another at a switchable port, such as the switchable port 706 as shown in FIG. 7, for example. Continuing this example with respect to the resonator branch 702.1, when the switching component 708 is open, the resonator branch 702.1 is “on,” and as a result contributes to the overall filter response of the AWR filter 700. When the switching component 708 is closed, however, the switchable port 706 of the resonant branch 702.1 is shorted to ground, and thus no longer contributing to the overall filter response of the AWR filter 700. The example of the switching component 708 turning the resonator branch on or off in this way may be extended to each resonant branch 702.1-702.N as shown in FIG. 7, although only the switching component 708 is labeled for the resonant branch 702.1 for purposes of brevity.

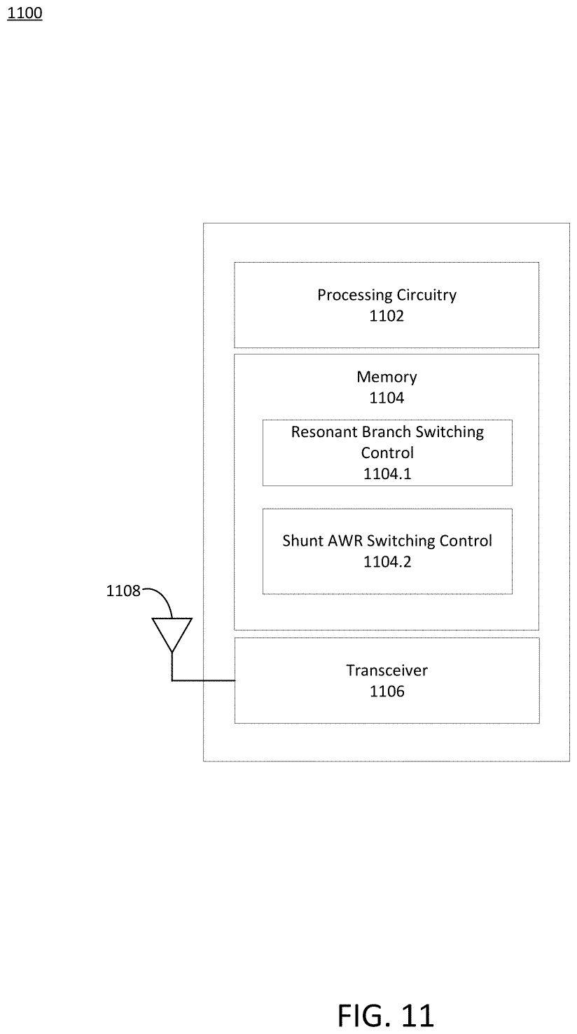

The switching components 708 as shown in FIG. 7 may be implemented as any suitable type of electronically-controlled switch. For example, each of the switching components 708 may be implemented using any suitable type of transistor switch (e.g. a single transistor GaN switch) that functions to selectively conduct the switchable ports 706 to ground, turning each resonant branch 702.1-702.N off, or to remain open, allowing each respective resonant branch 702.1-702.N to float and thus be turned on. In various aspects, the state of each switching component 708 may be controlled via any suitable type of control signal provided via any suitable type of device. For example, if the AWR filter 700 is implemented as part of a mobile device, the state of each of the switching components 708 may be controlled by one or more processors of the mobile device via a MAC layer or other suitable portion of the mobile device, as further discussed herein with reference to FIG. 11.

Although only two AWRs 704A, 704B are shown in FIG. 7 coupled to the switchable port 706, the aspects are not limited to this example. Instead, the aspects described herein include the use of any suitable number of AWRs 704 coupled in series with one another and to any suitable number of switchable ports, which may provide the same or different resonant configurations per each resonant branch 702.1-702.N. For example, as shown in FIG. 7, each of the resonant branches 702.1-702.N includes the same number of AWRs 704 (i.e., 2), with a single switching component 708 being coupled to each respective switchable port 706, thus independently controlling the resonant state of each resonant branch 702.1-702.N.

However, any of the resonant branches 702.1-702.N may alternatively include more than two AWRs 704 coupled in series with one another. As a general example, the number of AWRs 704 of any of the resonant branches 702.1-702.N may be represented as S. In such a case, any of the resonant branches 702.1-702.N having a number S of AWRs 704 may also include a number (S-1) of switching components 708. Thus, the resonant state of a resonant branch 702.1-702.N having more than two AWRs 704 may likewise be controlled by turning each of the (S-1) switching components 708 on or off at that particular resonant branch 702.1-702.N. In other words, the AWR filter 700 may include a switchable port 706 associated with each respective resonator branch 702.1-7021.N that is coupled to a respective switching component 708, and each respective switching component 708 may be configured to selectively couple its respective switchable port 706 to ground to turn that respective resonator branch 702.1-702.N on or off.

Again, aspects include the resonant branches 702.1-702.N having the same number or a different number of AWRs 704. For the programmable AWR filter 700, this means that the resonant state of some of the resonant branches 702.1-702.N may be controlled via a single switching component 708, whereas the resonant state of other resonant branches 702.1-702.N may be controlled via more than one switching component 708. Thus, by controlling the state of the switching components for the AWR filter 700, the combination of which resonant branch 702.1-702.N that contributes to the overall filter response of the AWR filter 700 may be controlled and dynamically adjusted.

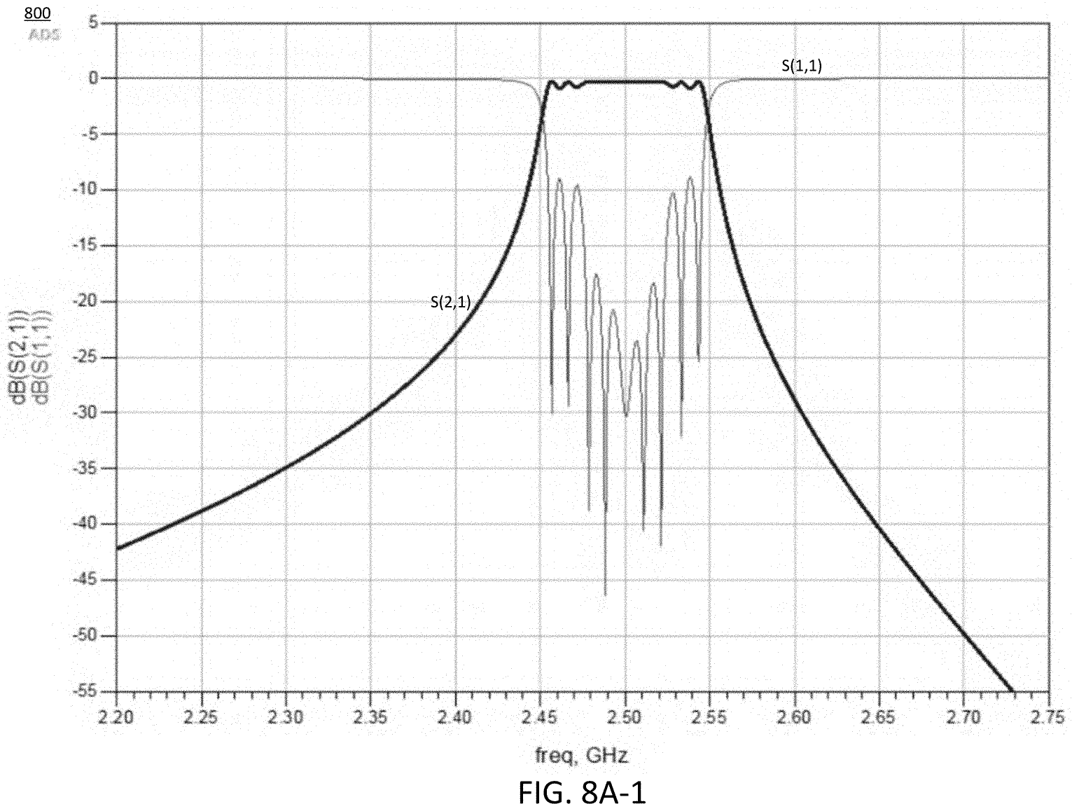

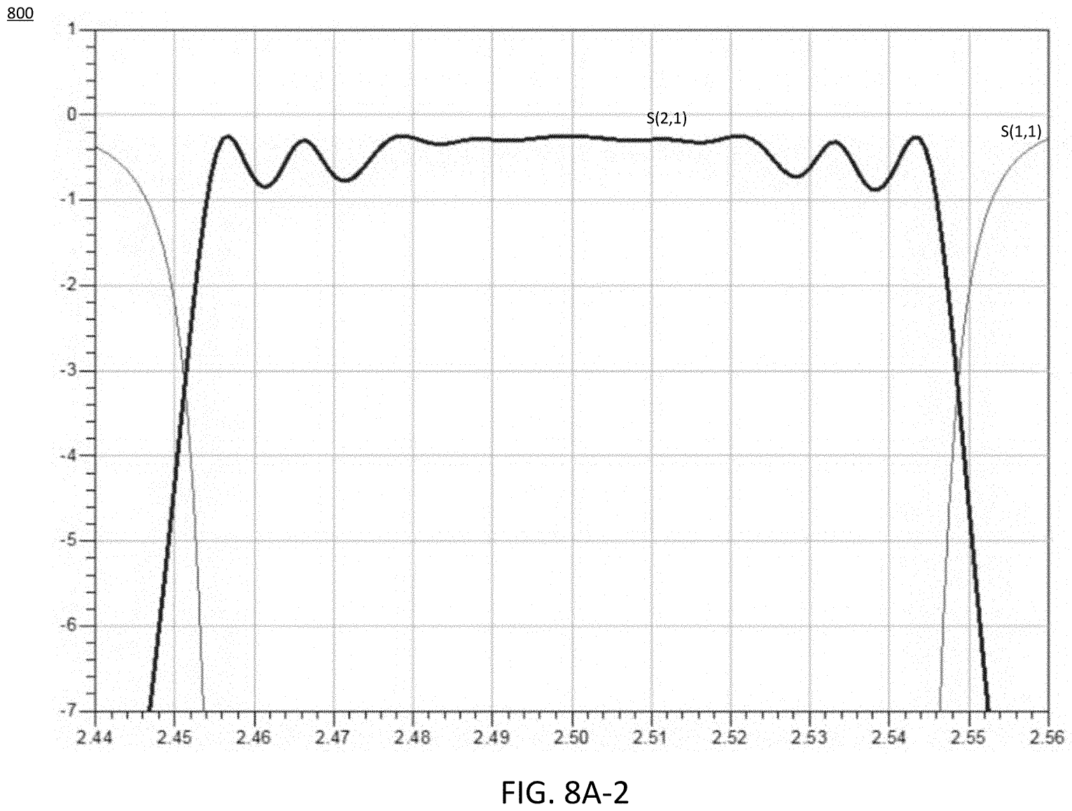

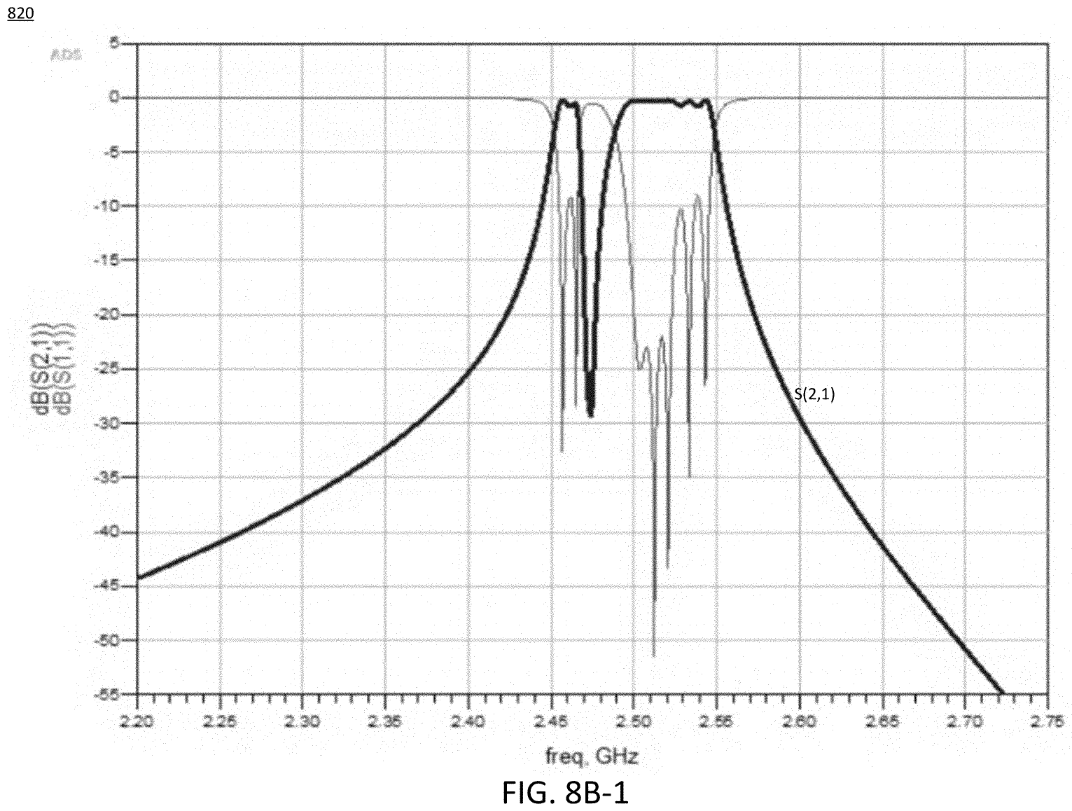

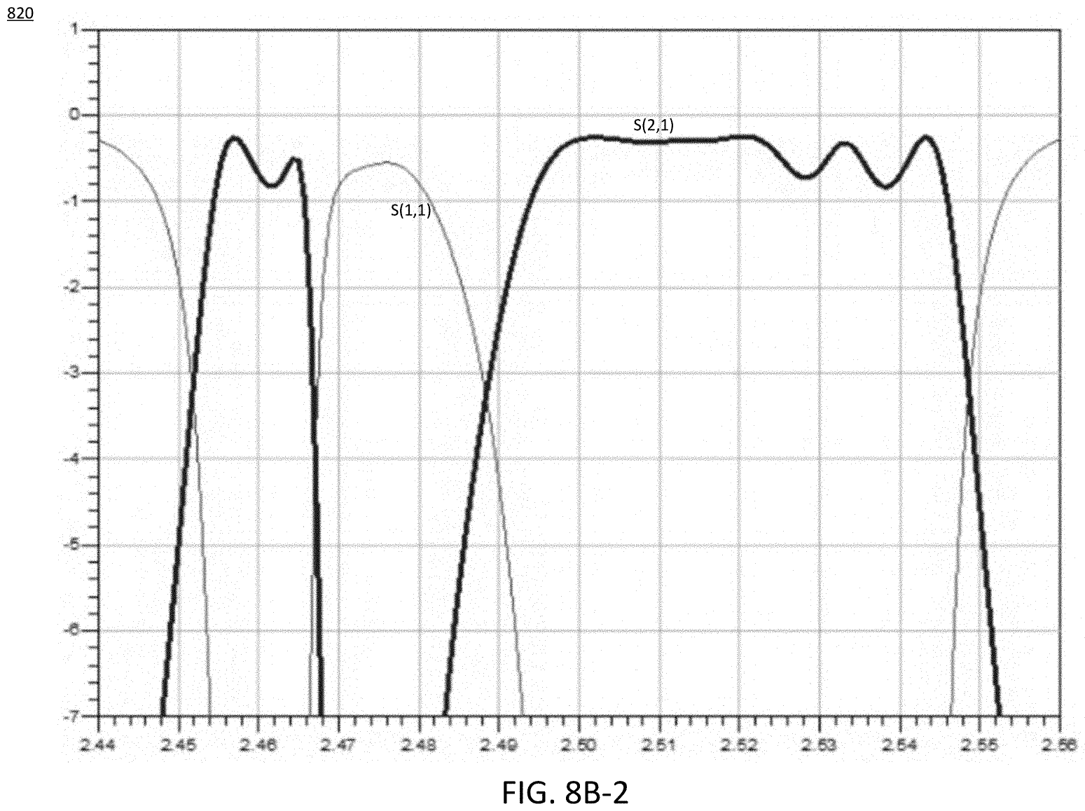

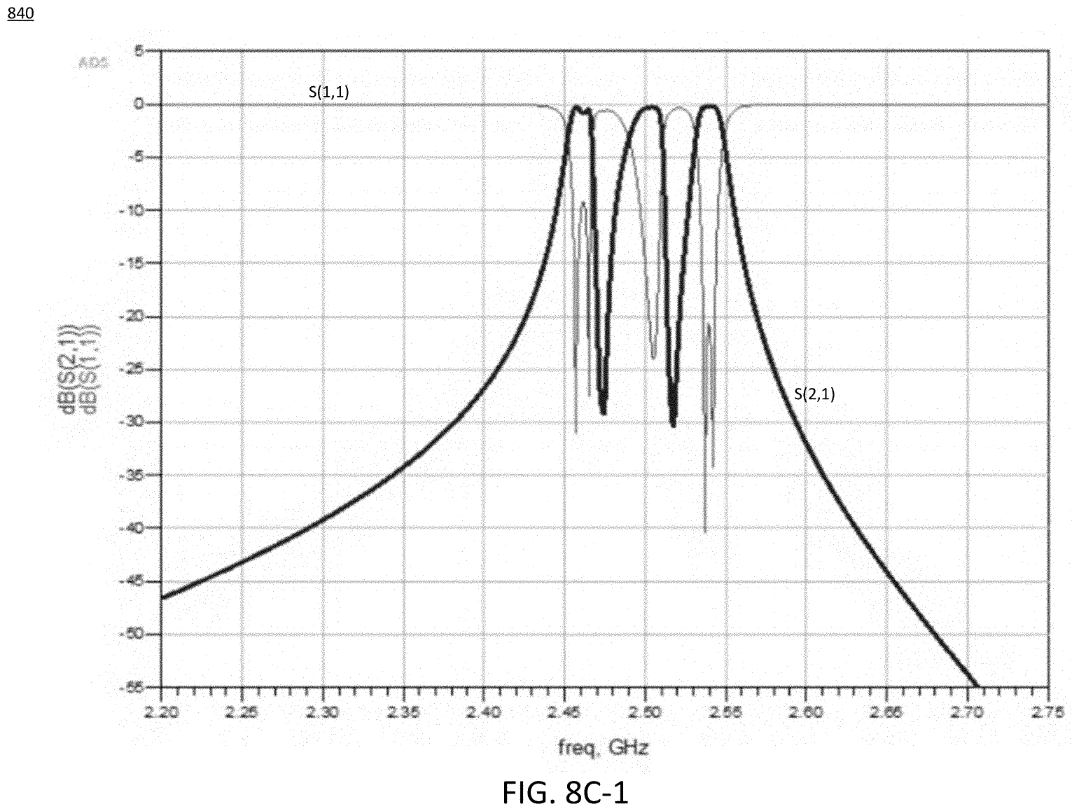

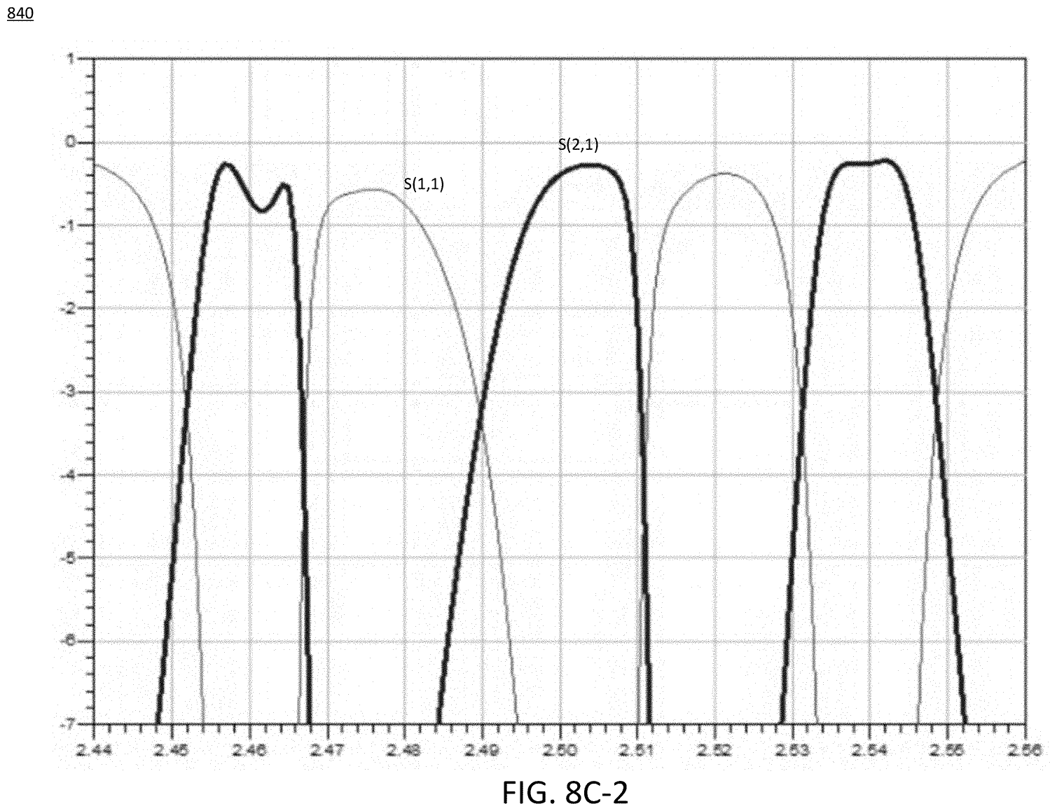

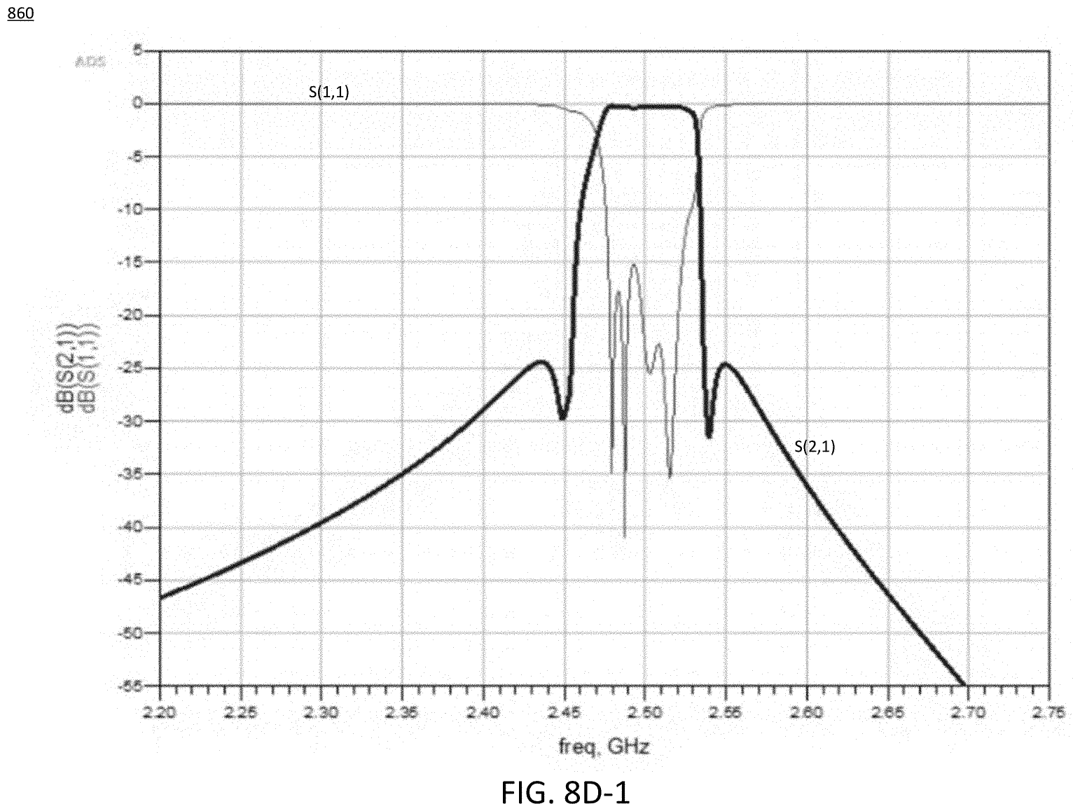

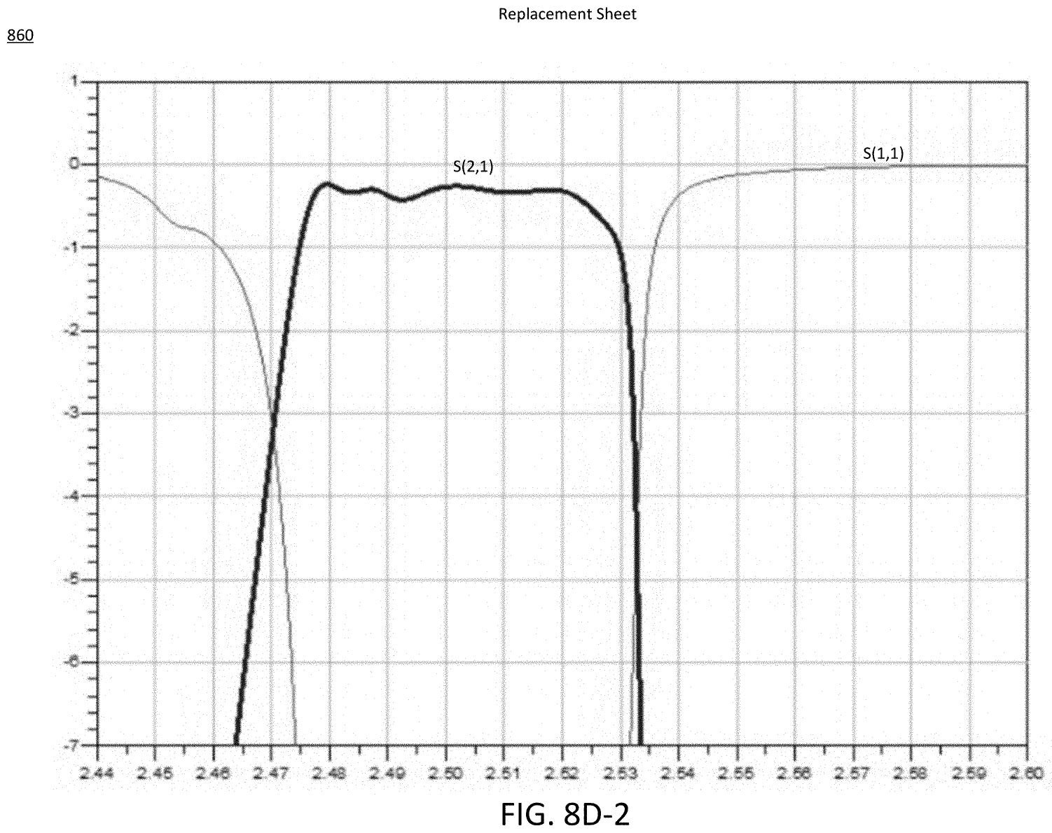

As discussed above for the AWR filter 400, each one of the resonator branches 702.1-702.N of the AWR filter 700 may also be associated with a different frequency band that represents a different portion of the operational passband of the AWR filter 700. Thus, as each respective resonator branch 702.1-702.N is turned on or off via its respective switching component 708, the filter response of the AWR filter 700 may be adjusted accordingly. This is further shown below with reference to the graphs shown in FIGS. 8A-1, 8A-2, 8B-1, 8B-2, 8C-1, 8C-2, 8D-1, and 8D-2.

FIGS. 8A-1, 8A-2, 8B-1, 8B-2, 8C-1, 8C-2, 8D-1, and 8D-2 illustrate graphs of exemplary filter responses for the programmable modular AWR filter architecture as shown in FIG. 7 having five resonator branches with different tuning configurations, in accordance with an aspect of the disclosure. For example, each of FIGS. 8A-1, 8A-2, 8B-1, 8B-2, 8C-1, 8C-2, 8D-1, and 8D-2 corresponds to the example architecture of the AWR filter 700 as shown in FIG. 7. The graphs shown in FIGS. 8A-1, 8A-2, 8B-1, 8B-2, 8C-1, 8C-2, 8D-1, and 8D-2 were simulated using an Agilent Advanced Design Systems (ADS) electronic circuit simulation tool. The simulation corresponds to the AWR filter 700 having 5 resonant branches 702.1-702.5. The switching component 708 for each resonant branch 702.1-702.5 was simulated as a single transistor GaN switch, using an assumed value of C_{off}Rₒₙ=100 fS, with Rₒₙ=1Ω and C_{off}=100 fF. It should be noted that the rejection level of a turned off branch band depends on Rₒₙ value. Thus, a deeper off band may be achieved by using a switching component 708 having a smaller on resistance at the cost of higher off capacitance (e.g. a larger size transistor).

Each of the graphs shown in FIGS. 8A-1, 8A-2, 8B-1, 8B-2, 8C-1, 8C-2, 8D-1, and 8D-2 shows the filter response of the AWR filter 700 as shown in FIG. 7 with different combination of the resonant branches 702.1-702.5 turned on or off. The graphs shown in FIGS. 8A-1, 8A-2, 8B-1, 8B-2, 8C-1, 8C-2, 8D-1, and 8D-2 represent the filter response using a return loss trace (RL or S(1,1)) and insertion loss trace (IL or (S(2,1)). For clarity and ease of explanation, each of the graphs shown in FIGS. 8A-1, 8A-2, 8B-1, 8B-2, 8C-1, 8C-2, 8D-1, and 8D-2 shows plots in two different scales, with the graphs 8A-1, 8B-1, 8C-1, and 8D-1 showing a larger scale covering approximately 550-600 MHz, and the graphs 8A-2, 8B-2, 8C-2, and 8D-2 providing a smaller, zoomed view of the passband of interest of each respective graph of 8A-1, 8B-1, 8C-1, and 8D-1, with the zoomed views covering approximately 120 MHz.

For example, FIGS. 8A-1 and 8A-2 show the filter response 800 of the AWR filter 700 with each of the resonant branches 702.1-702.5 turned on (i.e. each switching component 708 is open). FIGS. 8B-1 and 8B-2 show the filter response 820 of the AWR filter 700 with the second resonant branch 702.2 turned off (i.e. switching component 708 is closed for the resonant branch 702.2). FIGS. 8C-1 and 8C-2 show the filter response 840 of the AWR filter 700 with the second and fourth resonant branches 702.2, 702.4 turned off. FIGS. 8D-1 and 8D-2 show the filter response 860 of the AWR filter 700 with the first and fifth resonant branches 702.1, 702.5 turned off.

Thus, as can be observed by the changes to the filter response in the graphs shown in FIGS. 8A-1, 8A-2, 8B-1, 8B-2, 8C-1, 8C-2, 8D-1, and 8D-2, aspects include each of the resonant branches 702.1-702.5 representing a different portion of the overall passband of the AWR filter 700. For instance, in this example the first resonant branch 702.1 may represent the lowest frequency band within the overall passband of the AWR filter 700 as shown by the filter response 800 in FIGS. 8A-1 and 8A-2, whereas the fifth resonant branch 702.5 may represent the highest frequency band. Thus, by turning the “middle” resonant branches off as shown in FIGS. 8B-1 and 8B-2 and FIGS. 8C-1 and 8C-2, notches may be formed in the filter response. The filter response may also be narrowed by turning off the outer resonant branches 702.1, 702.5 as shown in FIGS. 8D-1 and 8D-2. Furthermore, and as discussed above with reference to the AWR filter 400, one or more inductors may be coupled between the first and second terminals of the AWR filter 700 (i.e. not shown, but parallel with each of the resonator branches 702.1-702.N) having any suitable values to provide sharper frequency roll-offs, if desired.

Additionally, a unique property of this topology is that when switching resonator branches on and off, required inductor matching values at the input and output ports do not change, and thus no additional matching programmability is required. This is because the switching a resonant branch off does not “remove” that particular branch, but rather shorts the resonant branch out while each branch is still coupled within the overall filter topology. This results in little change in the overall multi-branch impedance as seen with respect to the input and output ports.

In this way, the AWR filter 700 may function to allow flexible adjustment of the filter response by selectively combining specific resonant branches 702.1-702.N to generate different passband widths and notches as discussed above. However, in some applications it may be desirable to provide additional flexibility with respect to the overall shape of the filter response. For instance, certain LTE bands (e.g. band 25) are known to be close in frequency to Wi-Fi bands. Thus, it is desirable to further control the filter response in such scenarios.

Thus, to address these issues, aspects include the addition of switchable shunt AWRs, as further discussed below with reference to FIG. 9. In particular, FIG. 9 illustrates a schematic diagram of an exemplary programmable modular multi-branch AWR filter architecture with switchable resonator branches and switchable shunt resonators, in accordance with an aspect of the disclosure. The programmable AWR filter 900 as shown in FIG. 9 may be digitally programmable and include similar or identical components as the AWR filter 700 as shown and discussed herein with reference to FIG. 7; therefore, only differences between the AWR filters 700, 900 will be further discussed herein for purposes of brevity.

For instance, like the AWR filter 700, the AWR filter 900 also includes a source eₛ and corresponding source impedance Z_{S}, which may be associated with the input of the AWR filter 900 and represent any suitable source of time-varying electromagnetic signals. Furthermore, like the AWR filter 700, the AWR filter 900 also includes a load impedance Z_{L} that is associated with the output of the AWR filter 900 representing the impedance of the load of a particular component based upon the particular implementation of the AWR filter 900, and matching inductors Lₜ.

The AWR filter 900 also includes any suitable number of resonator branches 902.1-902.N connected in parallel with one another. The resonator branches 902.1-902.N may be arranged and implemented in a substantially similar or identical manner as the resonator branches 702.1-702.N as shown and described above with reference to FIG. 7. Thus, aspects include each resonator branch 902.1-902.N also including any suitable number of AWRs 904, such as the two AWRs 904.A, 904.B as shown in FIG. 9 with respect to the resonator branch 902.1. Again, the AWRs 904 may be implemented as any suitable type of acoustic wave resonator, such as the piezo-MEMS resonators discussed herein.

Furthermore, each of the resonator branches 902.1-902.N associated with the AWR filter 900 may include any suitable number of AWRs 904 coupled in series with one another and to a switchable port 906, which may be selectively coupled to ground via a coupled switchable component 908. Thus, similar to the AWR filter 700 as shown in FIG. 7, the AWR filter 900 is also configured such that any combination of the resonator branches 902.1-902.N may be turned on or off to contribute to the overall filter response of the AWR filter 900 to enable adjustment of the filter response as discussed above with respect to the AWR filter 700.

As discussed above for the AWR filters 400, 700, each one of the resonator branches 902.1-902.N of the AWR filter 900 may also be associated with a different frequency band that represents a different portion of the operational passband of the AWR filter 900. Thus, as each respective resonator branch 902.1-902.N is turned on or off via its respective switching component 908, the filter response of the AWR filter 900 may be adjusted accordingly.

And, as discussed above for the AWR filters 400, 700, each resonator branch 902.1-902.N also uses only coupled two-port acoustic resonators without additional passive components (no inductors or capacitors). Therefore, each of the resonant branches 902.1-902.N may also advantageously be implemented as an integrated design, such as a single integrated chip for instance.

The AWR filter 900 differs from the AWR filter 700 in that switchable shunt AWRs 910 are coupled in parallel with the two terminals of the AWR filter 900. In an aspect, the AWR filter 900 may include any suitable number of shunt AWRs 910, with four AWRs 910.1-910.4 being shown in FIG. 9 as an example and for ease of explanation. The shunt AWRs 910 may be implemented as any suitable type of acoustic wave resonator, and may be of a similar or identical type as the AWRs 904 included in each of the resonator branches 902.1-902.N. For example, each of the AWRs 904 may be implemented as a piezo-MEMS resonator as discussed herein with respect to the AWR filters 400, 700, and each of the shunt AWRs 910.1-910.4 may likewise be implemented using piezo-MEMS resonators as the AWRs 904.

However, each of the shunt AWRs 910.1-910.4 may be tuned to any suitable resonant frequency, which may be the same resonant frequency or a different resonant frequency than one another and/or the resonant frequencies of one or more of the AWRs 904. In an aspect, each of the shunt AWRs 910.1-910.4 may be tuned to contribute different notches and/or roll off characteristics to the overall frequency response of the AWR filter 900. In particular, aspects include each of the shunt AWRs 910.1-910.4 being coupled to a respective one of the two terminals of the AWR filter 900 as shown in FIG. 9 via a respective switching component 912.1-912.4. Thus, in addition to the selection of various combinations of the resonant branches 902.1-902.N via a first set of switching components represented by the switching component 908 corresponding to each respective resonant branch 902.1-902.N, combinations of each of the shunt AWRs 910.1-910.4 may also be selected (i.e., coupled to ground) via a second set of switching components represented by the switching component 912 corresponding to each respective shunt AWR 910.

In other words, the filter response associated with the AWR filter 900 may be a result of any selected combination of one or more of the resonant branches 902.1-902.N as well as any selected combination of the shunt AWRs 910.1-910.4 (4 in this example). The switchable components 912.1-912.4 may be implemented in a similar or identical manner as the switching components 708, 908 (e.g. as electronically-controlled components such as transistors), and may be electronically controlled in a similar or identical manner as the switching components 708, 908. However, it should be noted that the logic with respect to the switch state and the on and off state of the shunt AWRs 910 is opposite that of the resonant branches 902. For example, when one of the switching component 912 is closed, the corresponding shunt AWR 910 is “on” or coupled to the first or the second terminal of the AWR filter 900, as the case may be, and otherwise “off” and not contributing to the filter response of the AWR filter 900.

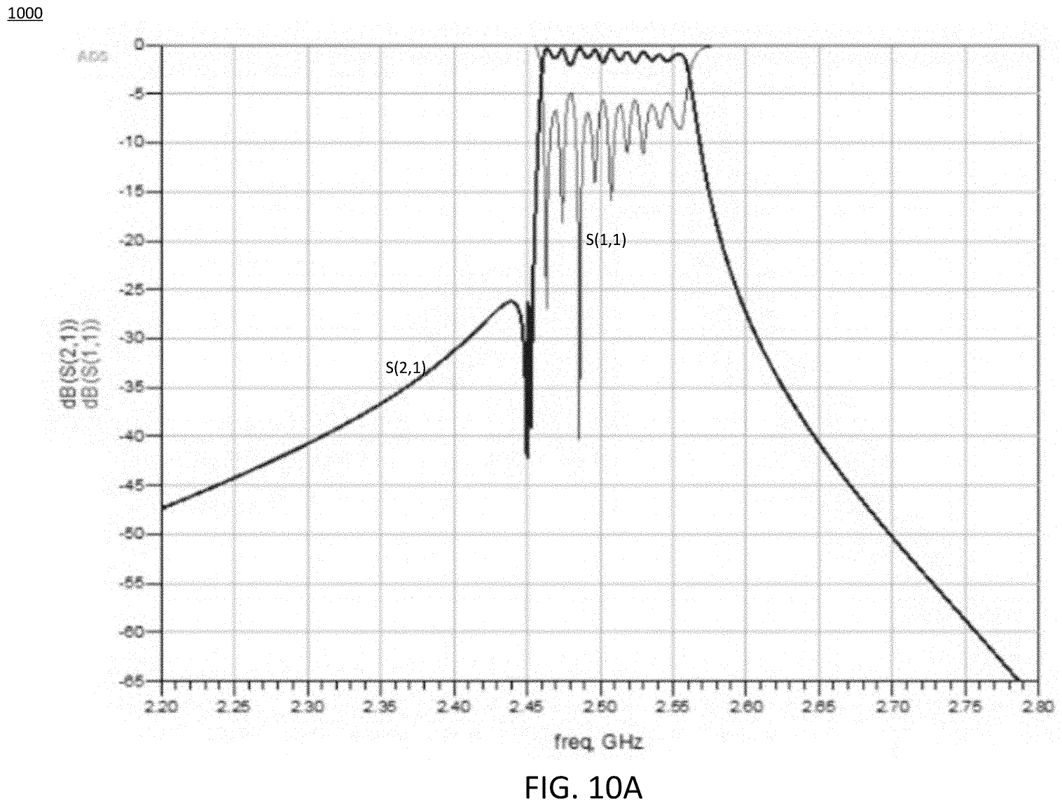

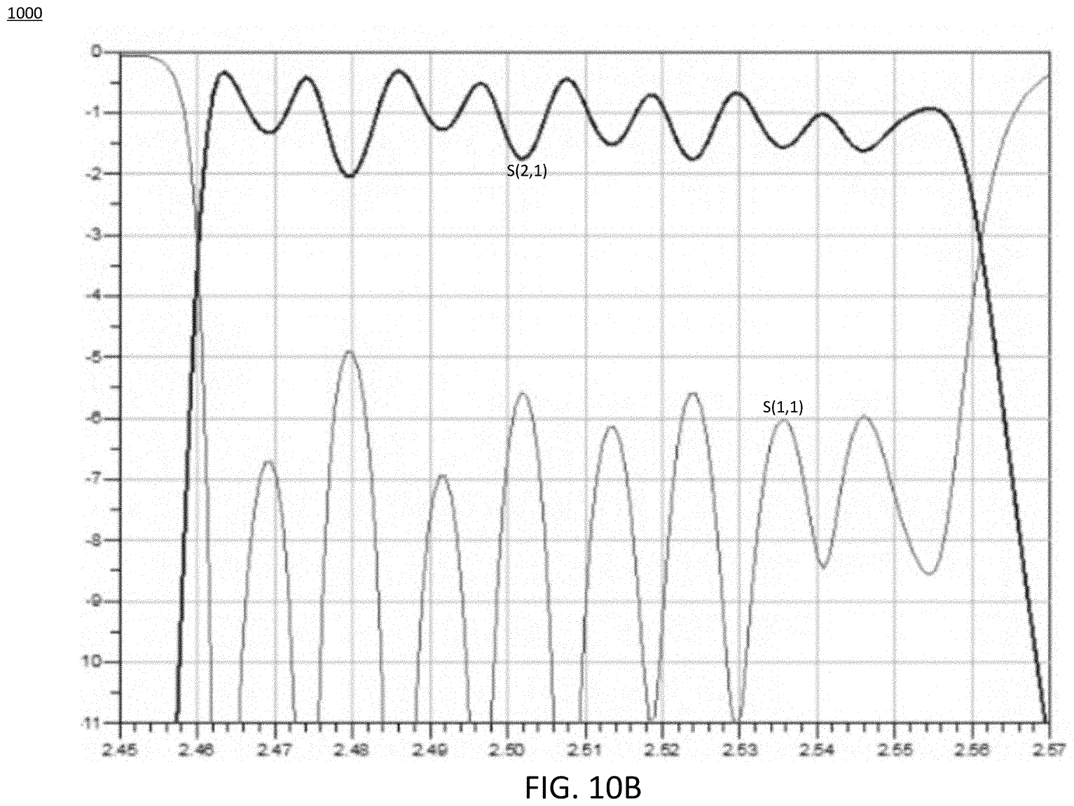

The use of the shunt AWRs 910 may further adjust the frequency response of the AWR filter 900 by introducing sharper roll-offs or deep notches. This may be achieved, as noted above, by tuning each of the shunt AWRs 910.1-910.4 at a desired notch frequency. Advantageously, when a shunt AWR 910 is decoupled from the AWR filter 900 (i.e. its corresponding switching component 912 is open), loading of the branch filter structure is substantially unaffected. This is further shown below with reference to FIGS. 10A-10B.

FIGS. 10A-10B illustrate graphs of exemplary filter responses for the programmable modular AWR filter architecture as shown in FIG. 9 having four resonator branches and two shunt resonators in a specific tuning configuration, in accordance with an aspect of the disclosure. The graphs shown in FIGS. 10A-10B were simulated using an Agilent Advanced Design Systems (ADS) electronic circuit simulation tool with the same parameters as discussed above for the switching components 912 as was used for the switching components 708 for the AWR filter 700 to produce the graphs shown in FIGS. 8A-1, 8A-2, 8B-1, 8B-2, 8C-1, 8C-2, 8D-1, and 8D-2 . The simulation corresponds to the AWR filter 900 having four of the resonant branches 902.1-902.5 switched on and two of the switchable notches active of the four switchable shunt AWRs 910.1-910.4, as shown in FIG. 9. Like the simulated example used to generate the graphs shown in FIGS. 8A-1, 8A-2, 8B-1, 8B-2, 8C-1, 8C-2, 8D-1, and 8D-2, each of the resonant branches 902.1-902.5 and the shunt AWRs 910.1-910.4 also have a kₜ² value of approximately 1.2%.

In other words, the graphs shown in FIGS. 10A-10B are the result of simulating turning off one of the five resonator branches 902.1-902.5 and coupling two of the four shunt AWRs 910.1-910.4 to the AWR filter 900. As can be seen from FIGS. 10A-10B, this tuning configuration provides an LTE band 25 RX filter with a 120 MHz passband bandwidth and 2 adjacent notches placed over the 2.4 GHz Wi-Fi band. From the graph 1000 in FIG. 10B, the −3 dB line can be easily viewed, indicating the filter response in this region of the passband.

Similar to the graphs shown in FIGS. 8A-1 and 8A-2, and 8B-1 and 8B-2, the graphs shown in FIGS. 10A-10B also represent the filter response using a return loss trace (RL or S(1,1)) and insertion loss trace (IL or S(2,1)). For clarity and ease of explanation, each of the graphs shown in FIGS. 10A-10B also show plots in two different scales, with the graph in FIG. 10A showing a larger scale covering approximately 600 MHz, and the graph in FIG. 10B providing a smaller, zoomed view of the passband of interest of the graph shown in FIG. 10A, with the zoomed view covering approximately 120 MHz.

Of course, as discussed above with reference to the AWR filters 400, 700, the AWR filter 900 may also implement one or more inductors coupled between the first and second terminals of the AWR filter 900 (i.e. not shown, but parallel with each of the resonator branches 902.1-902.N). These inductors may have any suitable values to provide even sharper frequency roll-offs, if desired.

FIG. 11 illustrates device, in accordance with an aspect of the disclosure. The device 1100 may be implemented as a standalone device and/or a component that is used for any suitable type of wireless communications implementing the AWR filtering topologies and techniques as discussed herein. For instance, the device 1100 may be implemented as a mobile phone, a laptop computer, a personal computer, a tablet computer, a wireless router, etc.

In an aspect, the device 100 may include processing circuitry 1102, a memory 1104, and a transceiver 1106 that is coupled to one or more antennas 1108. The components shown in FIG. 11 are provided for ease of explanation, and aspects include device 1100 implementing additional, less, or alternative components as those shown in FIG. 11. For example, the device 1100 may include one or more power sources, display interfaces, peripheral devices, ports, etc. To provide additional examples, the device 1100 may implement a transmitter and/or receiver in addition to or instead of the transceiver 1106 as shown in FIG. 11.

In an aspect, the various components of the device 1100 utilize and/or control one or more filter topologies such as the AWR filters 400, 700, 900 as shown and described with reference to FIGS. 4, 7, and 9 for example. For instance, the device 1100 may execute resonant branch switching control and/or shunt AWR switching control as discussed herein to adjust the filter response of an AWR filter, such as the AWR filters 700, 900, for instance.

To do so, processing circuitry 1102 may be configured as any suitable number and/or type of computer processors, which may function to control the device 1100 as discussed herein. Processing circuitry 1102 may be identified with one or more processors (or suitable portions thereof) implemented by the device 1100. As discussed herein, processing circuitry 1102 may, for example, be identified with one or more processors implemented by the device 1100 such as a host processor, a digital signal processor, one or more microprocessors, microcontrollers, an application-specific integrated circuit (ASIC), a baseband processor, part (or the entirety of a field-programmable gate array (FPGA), one or more MAC layers or other appropriate portions associated with hardware circuity, etc. In any event, aspects include the processing circuitry 1102 being configured to carry out instructions to perform arithmetical, logical, and/or input/output (I/O) operations, and/or to control the operation of one or more components of the device 1100 to perform various functions associated with the AWD filter aspects as described herein.

For example, the processing circuitry 1102 can include one or more microprocessor cores, memory registers, buffers, clocks, etc., and may generate electronic control signals associated with electronic components to control, tune, and/or modify the operation of one or more components of the device 1100 as discussed herein, which may include controlling, tuning, and/or modifying one of more components of an AWR filter (e.g., AWR filters 700, 900) as discussed herein, which may be incorporated as part of the device 1100. Moreover, aspects include processing circuitry 1102 communicating with and/or controlling functions associated with the memory 1104 and/or other components of the device 1100.

In an aspect, the memory 1104 stores data and/or instructions such that, when the instructions are executed by the processing circuitry 1102, the processing circuitry 1102 performs various functions as described herein. The memory 1104 can be implemented as any well-known volatile and/or non-volatile memory, including, for example, read-only memory (ROM), random access memory (RAM), flash memory, a magnetic storage media, an optical disc, erasable programmable read only memory (EPROM), programmable read only memory (PROM), etc. The memory 1104 can be non-removable, removable, or a combination of both.

For example, the memory 1104 may be implemented as a non-transitory computer readable medium storing one or more executable instructions such as, for example, logic, algorithms, code, etc. As further discussed below, the instructions, logic, code, etc., stored in the memory 1104 are represented by the various modules as shown in FIG. 11, which may enable the aspects disclosed herein to be functionally realized. Alternatively, if the aspects described herein are implemented via hardware, the modules shown in FIG. 11 associated with the memory 1104 may include instructions and/or code to facilitate control and/or monitor the operation of such hardware components. In other words, the modules shown in FIG. 11 are provided for ease of explanation regarding the functional association between hardware and software components. Thus, aspects include the processing circuitry 1102 executing the instructions stored in these respective modules in conjunction with one or more hardware components to perform the various functions associated with the aspects as further discussed herein.

In an aspect, the executable instructions stored in resonant branch switching control module 1104.1 may facilitate, in conjunction with the processing circuitry 1102, the calculation and/or identification of resonant branches of a respective AWR filter to turn on or off to achieve a desired filter response. This may include, for example, the generation of control signals to control a switching state associated with a first set of switching components (e.g., 708, 908) for one of the programmable AWR filter topologies as discussed herein (e.g., AWR filters 700, 900). Thus, the executable instructions stored in resonant branch switching control module 1104.1 may facilitate, in conjunction with the processing circuitry 1102, the selection of specific resonant branches (e.g., 702.1-702.N, 902.1-902.N) such that, when combined, produce a desired filter response. This desired filter response, and thus the determination of which resonant branches to selectively turn on and off, may be performed, for example, based upon a correlation of resonant branch combinations to the resulting frequency response using a priori knowledge (e.g., a predetermined specification), as part of a factory calibration, in response to detected or measured conditions, using lookup table entries, etc.

In an aspect, the executable instructions stored in shunt AWR switching control module 1104.2 may facilitate, in conjunction with the processing circuitry 1102, the calculation and/or identification of shunt AWRs of a respective AWR filter to turn on or off to achieve a desired filter response. This may include, for example, the generation of control signals to control a switching state associated with a second set of switching components (e.g., 912) for one of the programmable AWR filter topologies as discussed herein (e.g., AWR filter 900). Thus, the executable instructions stored in shunt AWR switching control module 1104.2 may facilitate, in conjunction with the processing circuitry 1102, the selection of specific shunt AWRs (e.g., 910) that, when combined, introduce the desired frequency roll-off and/or notch characteristics to provide the desired filter response. Again, this desired filter response, and thus the determination of which shunt AWRs to selectively turn on and off, may be performed, for example, based upon a correlation of shunt AWR combinations to the resulting frequency response using a priori knowledge (e.g., a predetermined specification), as part of a factory calibration, in response to detected or measured conditions, using lookup table entries, etc.

Therefore, in summary, the aspects described herein provide significant advantages over existing FEM filter solutions. Specifically, the aspects described herein provide a passive-free (no passive components) programmable topology for high-performance integrated AWR filters, which have a configurable and wide bandwidth that is independent of kₜ². Moreover, the AWR filter topologies discussed herein do not require costly trimming for high precision resonance frequency. The above-described aspects also function to quantize the desired broadband or multi-band passbands into band segments of width ˜kₜ², and offer digital on/off programmability of each segment to shape the passband as needed. Furthermore, the AWR filter aspects described above allow for notch placement at any desired frequency to enhance the passband edge roll-off or to create deep isolated stop-band notches. And, contrary to convention, a smaller kₜ² may actually be beneficial in this scheme by providing finer band granularity in shaping the desired passband(s).

### EXAMPLES

The following examples pertain to further aspects.

Example 1 is an acoustic wave resonator (AWR) filter, comprising: a first terminal; a second terminal; and a plurality of resonator branches, each of the plurality of resonator branches including at least a first AWR and a second AWR coupled in series with one another, wherein the plurality of resonator branches are coupled in parallel with one another such that each of the first AWRs from among the plurality of resonator branches are coupled to one another and to the first terminal, and each of the second AWRs from among the plurality of resonator branches are coupled to one another and to the second terminal.

In Example 2, the subject matter of Example 1, wherein each of the first AWRs and each of the second AWRs from among the plurality of resonator branches comprises a piezo micro-electromechanical system (MEMS) resonator having a first port and a second port.

In Example 3, the subject matter of any combination of Examples 1-2, wherein the first port of each of the first AWRs from among the plurality of resonator branches is coupled to the first terminal, and wherein the second port of each of the second AWRs from among the plurality of resonator branches is coupled to the second terminal.

In Example 4, the subject matter of any combination of Examples 1-3, wherein the second port of each respective one of the first AWRs from among the plurality of resonator branches is coupled to the first port of each respective one of the second AWRs from among the plurality of resonator branches.

In Example 5, the subject matter of any combination of Examples 1-4, wherein the second port of each respective one of the first AWRs from among the plurality of resonator branches is coupled directly to the first port of each respective one of the second AWRs from among the plurality of resonator branches.

In Example 6, the subject matter of any combination of Examples 1-5, wherein each of the plurality of resonator branches is formed as part of a single integrated chip.

In Example 7, the subject matter of any combination of Examples 1-6, wherein each one of the plurality of resonator branches is associated with a different frequency band that represents a different portion of an operational pass-band of the AWR filter.

Example 8 is a programmable acoustic wave resonator (AWR) filter, comprising: a first terminal; a second terminal; and a plurality of resonator branches, each of the plurality of resonator branches including a first AWR and a second AWR that are coupled in series with one another at a switchable port, wherein the plurality of resonator branches are coupled in parallel with one another such that each of the first AWRs from among the plurality of resonator branches are coupled to one another and to the first terminal, and each of the second AWRs from among the plurality of resonator branches are coupled to one another and to the second terminal, and wherein the switchable port associated with each respective one the plurality of resonator branches is configured to enable independent control of a resonant state of each of the plurality of resonator branches.

In Example 9, the subject matter of Example 8, wherein the switchable port associated with each respective one the plurality of resonator branches is coupled to a respective switching component, each respective switching component being configured to selectively couple the respective switchable port to ground to turn that respective resonator branch on or off.

In Example 10, the subject matter of any combination of Examples 8-9, wherein each one of the plurality of resonator branches is associated with a different frequency band that represents a different portion of the operational passband of the AWR filter, and wherein each respective one the plurality of resonator branches is turned on or off via each respective switching component to adjust a filter response of the AWR filter.

In Example 11, the subject matter of any combination of Examples 8-10, wherein each respective switching component associated with each one the plurality of resonator branches comprises an electronically-controllable transistor switch.

In Example 12, the subject matter of any combination of Examples 8-11, wherein each of the first AWRs and each of the second AWRs from among the plurality of resonator branches comprises a piezo micro-electromechanical system (MEMS) resonator having a first port and a second port.

In Example 13, the subject matter of any combination of Examples 8-12, wherein the first port of each of the first AWRs from among the plurality of resonator branches is coupled to the first terminal, and wherein the second port of each of the second AWRs from among the plurality of resonator branches is coupled to the second terminal.

In Example 14, the subject matter of any combination of Examples 8-13, wherein each of the plurality of resonator branches is formed as part of a single integrated chip.

Example 15 is a programmable acoustic wave resonator (AWR) filter, comprising: a first terminal; a second terminal; a plurality of resonator branches, each of the plurality of resonator branches including a first AWR and a second AWR that are coupled in series with one another; and a plurality of shunt AWRs, wherein the plurality of resonator branches are coupled in parallel with one another such that each of the first AWRs from among the plurality of resonator branches are coupled to one another and to the first terminal, and each of the second AWRs from among the plurality of resonator branches are coupled to one another and to the second terminal, wherein each respective one the plurality of resonator branches is configured to be selectively coupled to ground via a first set of switching components, and wherein each respective one the plurality of shunt AWRs is configured to be selectively coupled to ground via a second set of switching components.

In Example 16, the subject matter of Example 15, wherein each one of the plurality of resonator branches is associated with a different frequency band that represents a different portion of the operational passband of the AWR filter, and wherein each respective one the plurality of resonator branches is turned on or off via respective switching components from among the first set of switching components to adjust a filter response of the AWR filter.

In Example 17, the subject matter of any combination of Examples 15-16, wherein each respective one the plurality of shunt AWRs is turned on or off via respective switching components from among the second set of switching components to further adjust a filter response of the AWR filter.

In Example 18, the subject matter of any combination of Examples 15-17, wherein each respective one the plurality of shunt AWRs is turned on or off via respective switching components from among the second set of switching components to further adjust the filter response of the AWR filter by adjusting different notch locations in the filter response.

In Example 19, the subject matter of any combination of Examples 15-18, wherein (i) each of the first AWRs and each of the second AWRs from among the plurality of resonator branches, and (ii) each of the plurality of shunt AWRs comprise a piezo micro-electromechanical system (MEMS) resonator having a first port and a second port.

In Example 20, the subject matter of any combination of Examples 15-19, wherein each of the plurality of resonator branches and each of the plurality of shunt AWRs formed as part of a single integrated chip.

Example 21 is an acoustic wave resonator (AWR) filter, comprising: a first terminal means; a second terminal means; and a plurality of resonator branch means, each of the plurality of resonator branch means including at least a first AWR means and a second AWR means coupled in series with one another, wherein the plurality of resonator branch means are coupled in parallel with one another such that each of the first AWR means from among the plurality of resonator branch means are coupled to one another and to the first terminal means, and each of the second AWR means from among the plurality of resonator branch means are coupled to one another and to the second terminal means.

In Example 22, the subject matter of Example 21, wherein each of the first AWR means and each of the second AWR means from among the plurality of resonator branch means comprises a piezo micro-electromechanical system (MEMS) resonator means having a first port and a second port.

In Example 23, the subject matter of any combination of Examples 21-22, wherein the first port of each of the first AWR means from among the plurality of resonator branch means is coupled to the first terminal means, and wherein the second port of each of the second AWR means from among the plurality of resonator branch means is coupled to the second terminal means.

In Example 24, the subject matter of any combination of Examples 21-23, wherein the second port of each respective one of the first AWR means from among the plurality of resonator branch means is coupled to the first port of each respective one of the second AWR means from among the plurality of resonator branch means.

In Example 25, the subject matter of any combination of Examples 21-24, wherein the second port of each respective one of the first AWR means from among the plurality of resonator branch means is coupled directly to the first port of each respective one of the second AWR means from among the plurality of resonator branch means.

In Example 26, the subject matter of any combination of Examples 21-25, wherein each of the plurality of resonator branch means is formed as part of a single integrated chip.

In Example 27, the subject matter of any combination of Examples 21-26, wherein each one of the plurality of resonator branch means is associated with a different frequency band that represents a different portion of an operational pass-band of the AWR filter.

Example 28 is a programmable acoustic wave resonator (AWR) filter, comprising: a first terminal means; a second terminal means; and a plurality of resonator branch means, each of the plurality of resonator branch means including a first AWR means and a second AWR means that are coupled in series with one another at a switchable port, wherein the plurality of resonator branches are coupled in parallel with one another such that each of the first AWR means from among the plurality of resonator branch means are coupled to one another and to the first terminal means, and each of the second AWR means from among the plurality of resonator branch means are coupled to one another and to the second terminal means, and wherein the switchable port associated with each respective one the plurality of resonator branch means is configured to enable independent control of a resonant state of each of the plurality of resonator branch means.

In Example 29, the subject matter of Example 28, wherein the switchable port associated with each respective one the plurality of resonator branch means is coupled to a respective switching means, each respective switching means being configured to selectively couple the respective switchable port to ground to turn that respective resonator branch means on or off.

In Example 30, the subject matter of any combination of Examples 28-29, wherein each one of the plurality of resonator branch means is associated with a different frequency band that represents a different portion of the operational passband of the AWR filter, and wherein each respective one the plurality of resonator branch means is turned on or off via each respective switching means to adjust a filter response of the AWR filter.

In Example 31, the subject matter of any combination of Examples 28-30, wherein each respective switching means associated with each one the plurality of resonator branch means comprises an electronically-controllable transistor switch.

In Example 32, the subject matter of any combination of Examples 28-31, wherein each of the first AWR means and each of the second AWR means from among the plurality of resonator branch means comprises a piezo micro-electromechanical system (MEMS) resonator having a first port and a second port.

In Example 33, the subject matter of any combination of Examples 28-32, wherein the first port of each of the first AWR means from among the plurality of resonator branch means is coupled to the first terminal means, and wherein the second port of each of the second AWR means from among the plurality of resonator branch means is coupled to the second terminal means.

In Example 34, the subject matter of any combination of Examples 28-33, wherein each of the plurality of resonator branch means is formed as part of a single integrated chip.

Example 35 is a programmable acoustic wave resonator (AWR) filter, comprising: a first terminal means; a second terminal means; a plurality of resonator branch means, each of the plurality of resonator branch means including a first AWR means and a second AWR means that are coupled in series with one another; and a plurality of shunt AWR means, wherein the plurality of resonator branch means are coupled in parallel with one another such that each of the first AWR means from among the plurality of resonator branch means are coupled to one another and to the first terminal means, and each of the second AWR means from among the plurality of resonator branch means are coupled to one another and to the second terminal means, wherein each respective one the plurality of resonator branch means is configured to be selectively coupled to ground via a first set of switching means, and wherein each respective one the plurality of shunt AWR means is configured to be selectively coupled to ground via a second set of switching means.

In Example 36, the subject matter of Example 35, wherein each one of the plurality of resonator branch means is associated with a different frequency band that represents a different portion of the operational passband of the AWR filter, and wherein each respective one the plurality of resonator branch means is turned on or off via respective switching means from among the first set of switching means to adjust a filter response of the AWR filter.

In Example 37, the subject matter of any combination of Examples 35-36, wherein each respective one the plurality of shunt AWR means is turned on or off via respective switching means from among the second set of switching means to further adjust a filter response of the AWR filter.

In Example 38, the subject matter of any combination of Examples 35-37, wherein each respective one the plurality of shunt AWR means is turned on or off via respective switching means from among the second set of switching means to further adjust the filter response of the AWR filter by adjusting different notch locations in the filter response.

In Example 39, the subject matter of any combination of Examples 35-38, wherein (i) each of the first AWR means and each of the second AWR means from among the plurality of resonator branch means, and (ii) each of the plurality of shunt AWR means comprise a piezo micro-electromechanical system (MEMS) resonator having a first port and a second port.

In Example 40, the subject matter of any combination of Examples 35-39, wherein each of the plurality of resonator branch means and each of the plurality of shunt AWR means formed as part of a single integrated chip.

An apparatus as shown and described.

A method as shown and described.

### CONCLUSION

It should be noted that the aspects in which no additional passives are needed is stated as an example of an advantage of the broadband filter aspects and not as a limitation. Thus, if space, cost, or other considerations allow, the addition of passive coupling components (e.g. shunt inductors) between resonators may be useful to enhance each respective resonator branch bandwidth.

The aforementioned description of the specific aspects will so fully reveal the general nature of the disclosure that others can, by applying knowledge within the skill of the art, readily modify and/or adapt for various applications such specific aspects, without undue experimentation, and without departing from the general concept of the present disclosure. Therefore, such adaptations and modifications are intended to be within the meaning and range of equivalents of the disclosed aspects, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

References in the specification to “one aspect,” “an aspect,” “an exemplary aspect,” etc., indicate that the aspect described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is submitted that it is within the knowledge of one skilled in the art to affect such feature, structure, or characteristic in connection with other aspects whether or not explicitly described.

The exemplary aspects described herein are provided for illustrative purposes, and are not limiting. Other exemplary aspects are possible, and modifications may be made to the exemplary aspects. Therefore, the specification is not meant to limit the disclosure. Rather, the scope of the disclosure is defined only in accordance with the following claims and their equivalents.

Aspects may be implemented in hardware (e.g., circuits), firmware, software, or any combination thereof. Aspects may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general purpose computer.

For the purposes of this discussion, the term “processing circuitry” or “processor circuitry” shall be understood to be circuit(s), processor(s), logic, or a combination thereof. For example, a circuit can include an analog circuit, a digital circuit, state machine logic, other structural electronic hardware, or a combination thereof. A processor can include a microprocessor, a digital signal processor (DSP), or other hardware processor. The processor can be “hard-coded” with instructions to perform corresponding function(s) according to aspects described herein. Alternatively, the processor can access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary aspects described herein, processing circuitry can include memory that stores data and/or instructions. The memory can be any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

### Appendix

The following analysis provides additional details with respect to the design, manufacture, and tuning of AWRs for a respective branch of an AWR filter in accordance with the various aspects as shown and described herein. The following is explained with reference to the AWR filter 400 as shown in FIG. 4, although the following analysis is applicable to any of the AWRs and/or accompanying branches discussed herein, and may be implemented regardless of the number of in-series coupled AWRs implemented within a particular branch.

The following is provided as an example of the derivation of appropriate design parameters to implement a 2-port AWR filter topology in accordance with the aspects described above.

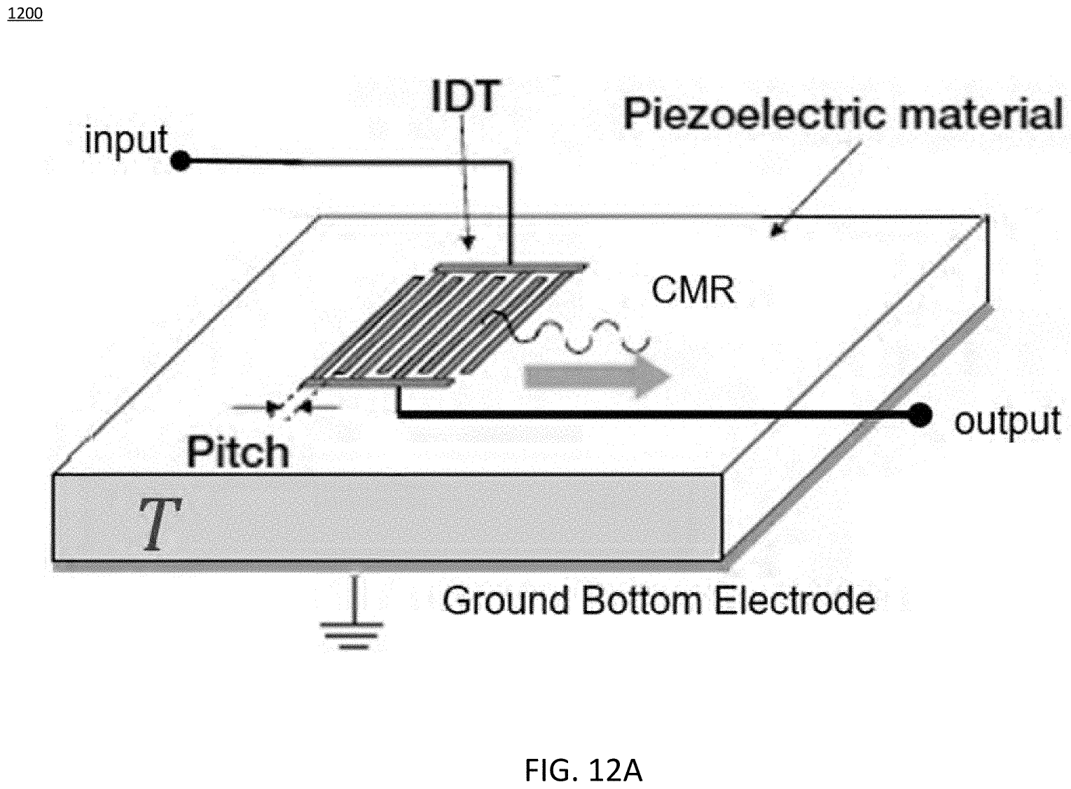

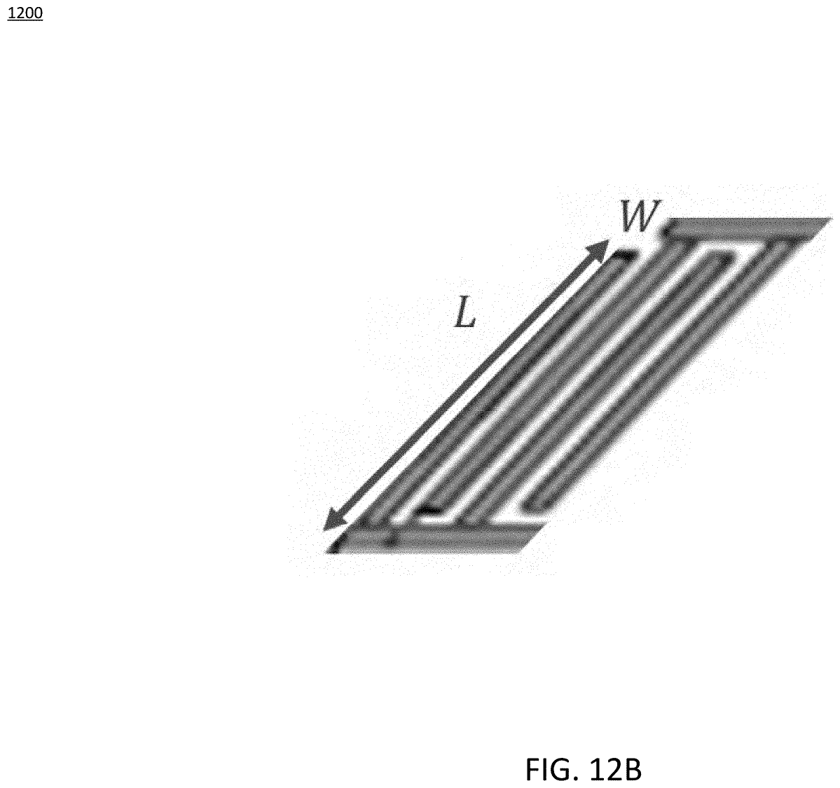

With reference to the inset 450 as shown in FIG. 4, the schematic symbol of an example 2-port AWR is shown. The AWRs discussed herein may be implemented, for example, as an example 2-port MEMS structure known as a 2-port contour mode resonator (CMR), which is shown in further detail in FIGS. 12A-12B. As shown in FIG. 12A, the input and output ports are depicted, as well as the ground electrode, which is coupled to the bottom of a piezoelectric material that functions as a substrate and has a corresponding thickness T. The resonator portion of the CMR is formed in this example using two interleaved inter-digitated electrodes as the input and output terminals (IDT) (i.e. ports), which are deposited on the top surface of the piezoelectric material and which may be implemented as a thin film, for instance. As shown in FIG. 12A and in further detail in FIG. 12B, the resonator structure includes design parameters such as the pitch, or spacing, between adjacent interleaved electrodes as well as L and W, which correspond to the length and width, respectively, of the IDT electrodes and which, together with the thickness T of the substrate, may be used to synthesize the AWRs and AWR-coupled branches (e.g., resonator branches 402.1-402.N as shown in FIG. 4) having the desired filter response characteristics for a particular application.

For example, the Butterworth-Van Dyke (BVD) circuit model of an AWR is shown in the inset 450 of FIG. 4, which represents the AWR using the following circuit parameters in conjunction with the aforementioned design parameters pitch, T, W, and L as follows.

$${C}_{O , in} = {n}_{in} {ɛ}_{33} {ɛ}_{O} \frac{WL}{T} , \\ {C}_{O , out} = {n}_{out} {ɛ}_{33} {ɛ}_{O} \frac{WL}{T} , \\ {R}_{M} = \frac{π}{8} \frac{T}{L} \frac{{ρ}_{eq}^{1 / 2}}{{E}_{eq}^{3 / 2} {d}_{31}^{2} Q} \frac{{n}_{in} + {n}_{out}}{{n}_{in}^{2}} = \frac{{π}^{2}}{8} \frac{1}{{ω}_{s} {k}_{t}^{2} Q} \frac{{n}_{in} + {n}_{out}}{{n}_{in}} \frac{1}{{C}_{O , in}} , \\ {L}_{M} = \frac{W}{8} \frac{T}{L} \frac{{ρ}_{eq}}{{E}_{eq}^{2} {d}_{31}^{2}} \frac{{n}_{in} + {n}_{out}}{{n}_{in}^{2}} = \frac{{π}^{2}}{8} \frac{1}{{ω}_{s}^{2}} \frac{1}{{k}_{t}^{2}} \frac{{n}_{in} + {n}_{out}}{{n}_{in}} \frac{1}{{C}_{O , in}} , \\ {C}_{M} = \frac{8}{{π}^{2}} \frac{WL}{T} {E}_{eq} {d}_{31}^{2} \frac{{n}_{in}^{2}}{{n}_{in} + {n}_{out}} = \frac{8}{{π}^{2}} {k}_{t}^{2} \frac{{n}_{in}}{{n}_{in} + {n}_{out}} {C}_{O , in} , \\ CMR - {f}_{s} ∼ \frac{1}{pitch}$$

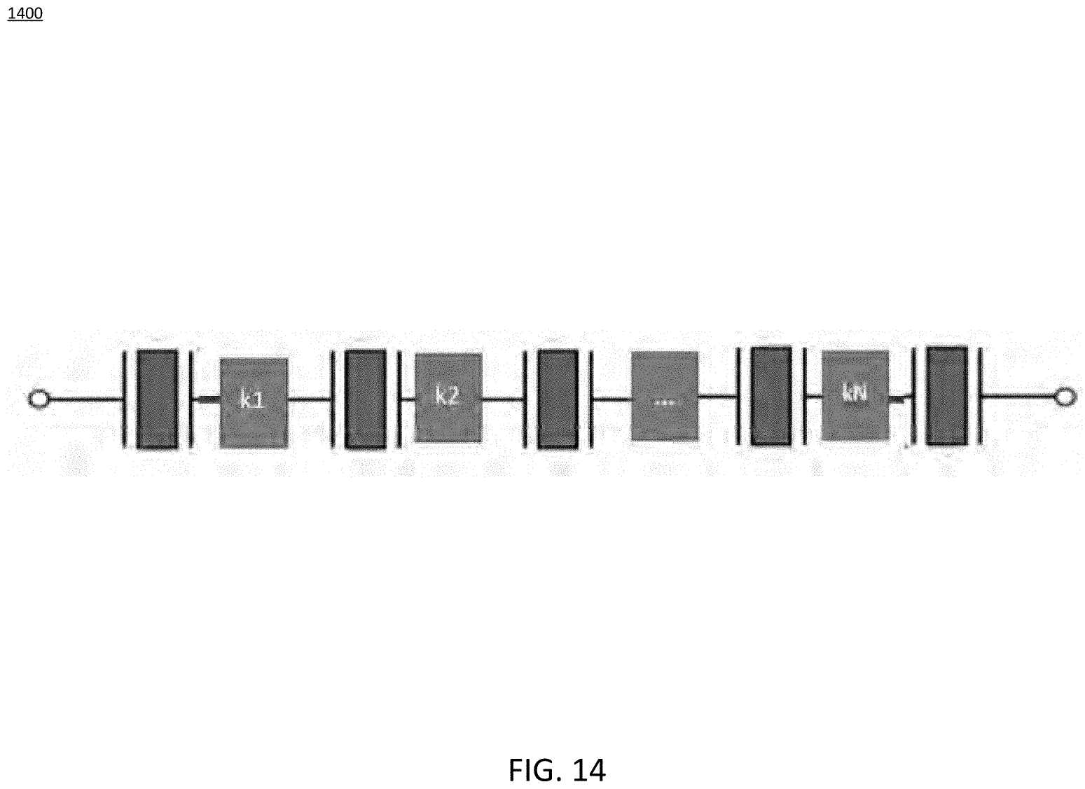

Furthermore, with reference to Jia-Sheng Hong, M. J. Lancaster, “Microstrip Filters for RF/Microwave Applications,” John Wiley & Sons, Inc. ISBNs: 0-47 1-38877-7: 0-47 1-22 16 1-9 (Electronic), FIG. 14 shows a non-uniformly coupled resonator array 1400. From this reference, the low-pass equivalent inductance for a bandpass filter centered at an angular frequency

$${ω}_{s} = \frac{1}{\sqrt{LC}}$$

may be provided together with a fractional bandwidth represented as FBW: L^{lp}=LωₛFBW.

With reference to the non-uniformly coupled resonator array 1400, the normalized (inverter) coupling coefficients Kᵢ for i=0, . . . , N+1 associated with each coupling structure describes the coupling behavior between adjacent coupled 2-port acoustic resonators, which is determined using the following mathematical expression:

$${K}_{i} = \frac{1}{\sqrt{{g}_{i - 1} \cdot {g}_{i}}}$$

The coupling structures may be understood as coupling inverters since they effectively behave like inverters coupling the AWRs to one another. Thus, with further reference to the AWR model shown in the inset 450 of FIG. 4, the following parameters may thus be derived as follows:

Low-pass equivalent inductance for bandpass filter centered at angular frequency ωₛ and fractional bandwidth FBW: L^{lp}=LωₛFBW

$${ω}_{s} = \frac{1}{\sqrt{L C}}$$

From the previous patent application [5] we have:

$${C}_{m} = p {C}_{01} where p = \frac{8}{{π}^{2}} {k}_{t}^{2} ⇒ {L}_{m} = \frac{1}{{ω}_{s}^{2} p {C}_{0}} ⇒ \{ \begin{matrix}{K}_{1} = \sqrt{\frac{{R}_{S} {L}_{m 1}^{lp}}{{g}_{0} {g}_{1}}} = \sqrt{\frac{FBW {ω}_{s}}{{ω}_{s 1}^{2} {pC}_{01}}} \frac{1}{\sqrt{{g}_{0} {g}_{1}}} & \begin{matrix}Normalized {R}_{S} = {R}_{L} = 1 & i = 1\end{matrix} \\ {K}_{N + 1} = \sqrt{\frac{{R}_{L} {L}_{mN}^{lp}}{{g}_{N} {g}_{N + 1}}} = \sqrt{\frac{FBW {ω}_{s}}{{ω}_{sN}^{2} {pC}_{0 N}}} \frac{1}{\sqrt{{g}_{N} {g}_{N + 1}}} & i = N + 1 \\ {K}_{i} = \sqrt{\frac{{L}_{mi - 1}^{lp} {L}_{mi}^{lp}}{{g}_{i - 1} {g}_{i}}} = \frac{FBW}{p \sqrt{{C}_{0 i - 1} {C}_{0 i}}} \frac{{ω}_{s}}{{ω}_{si} {ω}_{s - 1}} \frac{1}{\sqrt{{g}_{i - 1} {g}_{i}}} & else\end{matrix}$$

Where gᵢ values are filter polynomial element values with established classic theory or look up tables e.g table 1 and table 2.
On the other hand, in a lumped immitance inverter using capacitance value of C₀:

$${K}_{i} = \frac{1}{{ω}_{s} {Z}_{0} {C}_{r}} = \frac{1}{{ω}_{s} {C}_{r}}$$

for a normalized model where line characteristic impedance Z₀=1.

Furthermore, with respect to performing a resonator branch synthesis for a branch having two coupled AWRs as an example, a resonator branch may be modeled as shown below, with the index i representing the number of AWRs.

The circuit parameters derived from the modeling of the single AWR discussed directly above may then be applied to the BVD circuit model as shown in the inset 450 of FIG. 4 to derive the following circuit model for two coupled AWRs with properties as follows.

The above circuit model may then be replaced with another model that lumps the coupled capacitor elements together, and represents a coupling between these adjacent components using the properties represented in Equation A1 below:

$${K}_{i} = \frac{1}{{ω}_{s} ( C {0}_{i - 1} + C {0}_{t} ) {Z}_{0}} \qquad Eqn . A 1$$

The application of the equation A1 thus transforms the original circuit model of two adjacent coupled AWRs as follows:

The following calculations may then be applied to the derived circuit model to synthesize the desired resonator properties for a particular resonator branch (e.g. branch 402.1). For example, an N resonator branch design centered at ωₛ having a fractional bandwidth FBW may be derived recursively from the above equation A1 using a numerical computation starting from i=1. As an illustrative example, using a derivation of N=4 resonators for a single resonator branch, the resonator frequency fₛᵢ or ωₛᵢ, and capacitor size C0₁ for i=1, 2, . . . 4 may be expressed as follows:

$${C}_{ri} = \frac{1}{{ω}_{s} {K}_{i}} = \frac{{ω}_{si} {ω}_{si - 1}}{{ω}_{s}^{2}} \frac{p \sqrt{{C}_{0 i - 1} {C}_{0 i}} \sqrt{{g}_{i - 1} {g}_{i}}}{FBW} ;$$

$${Cr}_{1 and N + 1} = \frac{{ω}_{s 1}}{{ω}_{s}} \sqrt{\frac{{pC}_{0 i}}{{ω}_{s} FBW}} \sqrt{{g}_{i - 1} {g}_{i}}$$

Assuming symmetric filter, in the middle we have g₂=g₃:

$$2 {C}_{02} = \frac{{ω}_{s 2}^{2}}{{ω}_{s}^{2}} \frac{{pC}_{02} {g}_{2}}{FBW} ⇒ \frac{{ω}_{s 2}^{2}}{{ω}_{s}^{2}} \frac{{pg}_{2}}{FBW} = 2 ⇒ {ω}_{s 2} = {ω}_{s} \sqrt{\frac{2 FBW}{{pg}_{2}}}$$

$${C}_{01} + {C}_{02} = \frac{{ω}_{s 1} {ω}_{s 2}}{{ω}_{s}^{2}} \frac{p \sqrt{{C}_{01} {C}_{02}} \sqrt{{g}_{1} {g}_{2}}}{FBW} = \frac{{ω}_{s 1}}{{ω}_{s}} \sqrt{\frac{2 {pg}_{1}}{FBW} {C}_{01} {C}_{02}} = \frac{{ω}_{s 1}}{{ω}_{s}} \sqrt{\frac{{pg}_{0} {g}_{1}}{{ω}_{s} FBW}} \frac{{ω}_{s 1}}{{ω}_{s}} \sqrt{\frac{2 {pg}_{1}}{FBW} {C}_{02}} = {( \frac{{ω}_{s 1}}{{ω}_{s}} )}^{2} \frac{{pg}_{1}}{FBW} \sqrt{\frac{2 {g}_{01}}{{ω}_{s}}} \sqrt{{C}_{02}}$$

$${C}_{02} - {( \frac{{ω}_{s 1}}{{ω}_{s}} )}^{2} \frac{{pg}_{1}}{FBW} \sqrt{\frac{2 {g}_{0}}{{ω}_{s}}} \sqrt{{C}_{02}} + {( \frac{{ω}_{s 1}}{{ω}_{s}} )}^{2} \frac{{pg}_{0} {g}_{1}}{{ω}_{s} FBW} = 0$$

$$Δ = {( \frac{{ω}_{s 1}}{{ω}_{s}} )}^{4} {( \frac{{pg}_{1}}{FBW} )}^{2} \frac{2 {g}_{0}}{{ω}_{s}} - 4 {( \frac{{ω}_{s 1}}{{ω}_{s}} )}^{2} \frac{{pg}_{0} {g}_{1}}{{ω}_{s} FBW} = 2 {( \frac{{ω}_{s 1}}{{ω}_{s}} )}^{2} \frac{{pg}_{0} {g}_{1}}{{ω}_{s} FBW} [ {( \frac{{ω}_{s 1}}{{ω}_{s}} )}^{2} \frac{{pg}_{1}}{FBW} - 2 ]$$

$${( \frac{{ω}_{s 1}}{{ω}_{s}} )}^{2} \frac{{pg}_{1}}{FBW} - 2 \geq 0 ⇒ {FBW}_{max} = {( \frac{{ω}_{s 1}}{{ω}_{s}} )}^{2} \frac{{pg}_{1}}{2}$$

$$\sqrt{{C}_{02}} = {( \frac{{ω}_{s 1}}{{ω}_{s}} )}^{2} \frac{{pg}_{1}}{2 {FBW}_{max}} \sqrt{\frac{2 {g}_{0}}{{ω}_{s}}} = \sqrt{\frac{2 {g}_{0}}{{ω}_{s}}} ⇒ for max FBW \to {C}_{02} = \frac{2 {g}_{0}}{{ω}_{s} {Z}_{0}}$$

$$\sqrt{{C}_{01}} = \frac{{ω}_{s 1}}{{ω}_{s}} \sqrt{\frac{{pg}_{0} {g}_{1}}{{ω}_{s} {FBW}_{max}}} = \frac{{ω}_{s 1}}{{ω}_{s}} \sqrt{\frac{{pg}_{0} {g}_{1}}{{{ω}_{s} ( \frac{{ω}_{s 1}}{{ω}_{s}} )}^{2} \frac{{pg}_{1}}{2}}} = \sqrt{\frac{2 {g}_{0}}{{ω}_{s}}} ⇒ {C}_{01} = \frac{2 {g}_{0}}{{ω}_{s} {Z}_{0}}$$

$$C {0}_{1} = \frac{1}{{ω}_{s} {K}_{1}}$$

$$C {0}_{1} + C {0}_{2} = \frac{1}{{ω}_{s} {K}_{2}} ⇒ C {0}_{2} = \frac{1}{{ω}_{s} {K}_{2} {Z}_{0}} - \frac{1}{{ω}_{s} {K}_{1} {Z}_{0}} = \frac{1}{{ω}_{s} {Z}_{0}} ( \frac{1}{{K}_{2}} - \frac{1}{{K}_{1}} )$$

$$C {0}_{2} + C {0}_{3} = \frac{1}{{ω}_{s} {K}_{3}} ⇒ C {0}_{3} = \frac{1}{{ω}_{s} {K}_{3} {Z}_{0}} - C {0}_{2} = \frac{1}{{ω}_{s} {Z}_{0}} ( \frac{1}{{K}_{3}} - \frac{1}{{K}_{2}} + \frac{1}{{K}_{1}} )$$

$$…$$

$$C {0}_{i} = \frac{1}{{ω}_{s}} {\sum }_{j = 1}^{i} {( - 1 )}^{i - j} \frac{1}{{K}_{j}} ;$$

$$…$$

$$C {0}_{N - 1} + C {0}_{N} = \frac{1}{{ω}_{s} {K}_{N} {Z}_{0}} ⇒ C {0}_{N} = \frac{1}{{ω}_{s}} {\sum }_{j = 1}^{N} {( - 1 )}^{N - j} \frac{1}{{K}_{j}}$$

$$Also C {0}_{N} = \frac{1}{{ω}_{s} {Z}_{0} {K}_{N + 1}} ;$$

$$\frac{1}{{K}_{N + 1}} = {\sum }_{j = 1}^{N} {( - 1 )}^{N - j} \frac{1}{{K}_{j}} = \frac{1}{{K}_{1}}$$

with symmetric coefficients

### But

$${C}_{0} = n {ɛ}_{33} {ɛ}_{0} \frac{{A}^{finger}}{T} = {ɛ}_{33} {ɛ}_{0} \frac{{A}^{e}}{T}$$

where:
n=is the number of input or output fingers
A^{finger}=WL; Finger Area=width×Length of a finger
A^{e}=nWL; Electrode area

### T=Piezo Thickness

$$Reference electrode area = {A}_{1}^{e} = \frac{T}{{e}_{33} {e}_{0}} C {0}_{1} = \frac{T}{{ɛ}_{33} {ɛ}_{0}} \frac{1}{{ω}_{s} {Z}_{0}} \frac{1}{{K}_{1}}$$

$${A}_{i}^{e} = \frac{T}{{ɛ}_{33} {ɛ}_{0}} C {0}_{i} = \frac{T}{{ɛ}_{33} {ɛ}_{0}} \frac{1}{{ω}_{s} {Z}_{0}} {\sum }_{j = 1}^{i} {( - 1 )}^{i - j} \frac{1}{{K}_{j}} = {A}_{1}^{e} {\sum }_{j = 1}^{i} {( - 1 )}^{i - j} \frac{{K}_{1}}{{K}_{j}}$$

$${A}_{i}^{e} = {A}_{1}^{e} {\sum }_{j = 1}^{i} {( - 1 )}^{i - j} \frac{{K}_{1}}{{K}_{j}}$$

The symmetric coefficients noted above may thus be utilized in conjunction with known filter design techniques depending upon the number of overall elements used for a particular branch design to derive the desired filter response properties for a particular application.

1. An acoustic wave resonator (AWR) filter, comprising:
a first terminal;
a second terminal; and
a plurality of resonator branches, each of the plurality of resonator branches including at least a first AWR and a second AWR coupled in series with one another,
wherein the plurality of resonator branches are coupled in parallel with one another such that each of the first AWRs from among the plurality of resonator branches are coupled to one another and to the first terminal, and each of the second AWRs from among the plurality of resonator branches are coupled to one another and to the second terminal,
wherein each respective one of the plurality of resonator branches represents a different quantized bandwidth and has a selectively controlled resonant state that contributes to a different portion of an operational passband of a filter response associated with the AWR filter, and
wherein when each respective one of the plurality of resonator branches is in a resonant state, each different portion of the operational passband of the filter response associated with the AWR filter, which is represented by each respective one of the plurality of resonator branches, is combined to yield an entirety of the operational passband of the filter response associated with the AWR filter.

2. The AWR filter of claim 1, wherein each of the first AWRs and each of the second AWRs from among the plurality of resonator branches comprises a piezo micro-electromechanical system (MEMS) resonator having a first port and a second port.

3. The AWR filter of claim 2, wherein the first port of each of the first AWRs from among the plurality of resonator branches is coupled to the first terminal, and
wherein the second port of each of the second AWRs from among the plurality of resonator branches is coupled to the second terminal.

4. The AWR filter of claim 3, wherein the second port of each respective one of the first AWRs from among the plurality of resonator branches is coupled to the first port of each respective one of the second AWRs from among the plurality of resonator branches.

5. The AWR filter of claim 4, wherein the second port of each respective one of the first AWRs from among the plurality of resonator branches is coupled directly to the first port of each respective one of the second AWRs from among the plurality of resonator branches.

6. The AWR of claim 1, wherein each of the plurality of resonator branches is formed as part of a single integrated chip.

7. The AWR of claim 1, wherein each one of the plurality of resonator branches is associated with a different frequency band that represents a different portion of an operational pass-band of the AWR filter.

8. A programmable acoustic wave resonator (AWR) filter, comprising:
a first terminal;
a second terminal; and
a plurality of resonator branches, each of the plurality of resonator branches including a first AWR and a second AWR that are coupled in series with one another at a switchable port,
wherein the plurality of resonator branches are coupled in parallel with one another such that each of the first AWRs from among the plurality of resonator branches are coupled to one another and to the first terminal, and each of the second AWRs from among the plurality of resonator branches are coupled to one another and to the second terminal,
wherein the switchable port associated with each respective one of the plurality of resonator branches is configured to enable independent control of a resonant state of each of the plurality of resonator branches, and
wherein each respective one of the plurality of resonator branches represents a different quantized bandwidth such that the independently controlled resonant state contributes to a different portion of an operational passband of a filter response associated with the AWR filter, and
wherein when each respective one of the plurality of resonator branches is in a resonant state, each different portion of the operational passband of the filter response associated with the AWR filter, which is represented by each respective one of the plurality of resonator branches, is combined to yield an entirety of the operational passband of the filter response associated with the AWR filter.

9. The programmable AWR filter of claim 8, wherein the switchable port associated with each respective one of the plurality of resonator branches is coupled to a respective switching component, each respective switching component being configured to selectively couple the respective switchable port to ground to turn that respective resonator branch on or off.

10. The programmable AWR of claim 9,
wherein each respective one of the plurality of resonator branches is turned on or off via each respective switching component to adjust a filter response of the AWR filter.

11. The programmable AWR filter of claim 9, wherein each respective switching component associated with each one of the plurality of resonator branches comprises an electronically-controllable transistor switch.

12. The programmable AWR filter of claim 8, wherein each of the first AWRs and each of the second AWRs from among the plurality of resonator branches comprises a piezo micro-electromechanical system (MEMS) resonator having a first port and a second port.

13. The programmable AWR filter of claim 12, wherein the first port of each of the first AWRs from among the plurality of resonator branches is coupled to the first terminal, and
wherein the second port of each of the second AWRs from among the plurality of resonator branches is coupled to the second terminal.

14. The programmable AWR of claim 8, wherein each of the plurality of resonator branches is formed as part of a single integrated chip.

15. A programmable acoustic wave resonator (AWR) filter, comprising:
a first terminal;
a second terminal;
a plurality of resonator branches, each of the plurality of resonator branches including a first AWR and a second AWR that are coupled in series with one another; and
a plurality of shunt AWRs,
wherein the plurality of resonator branches are coupled in parallel with one another such that each of the first AWRs from among the plurality of resonator branches are coupled to one another and to the first terminal, and each of the second AWRs from among the plurality of resonator branches are coupled to one another and to the second terminal,
wherein each respective one of the plurality of resonator branches is configured to be selectively coupled to ground via a first set of switching components, each respective one of the plurality of resonator branches representing a different quantized bandwidth such that the selectively coupling to ground controls a resonant state of each respective one of the plurality of resonator branches, which controls a contribution a different portion of an operational passband of a filter response associated with the AWR filter,
wherein each respective one of the plurality of shunt AWRs is configured to be selectively coupled to ground via a second set of switching components, and
wherein when each respective one of the plurality of resonator branches is in a resonant state, each different portion of the operational passband of the filter response associated with the AWR filter, which is represented by each respective one of the plurality of resonator branches, are combined to yield an entirety of the operational passband of the filter response associated with the AWR filter.

16. The programmable AWR filter of claim 15,
wherein each respective one of the plurality of resonator branches is turned on or off via respective switching components from among the first set of switching components to adjust a filter response of the AWR filter.

17. The programmable AWR filter of claim 16, wherein each respective one of the plurality of shunt AWRs is turned on or off via respective switching components from among the second set of switching components to further adjust a filter response of the AWR filter.

18. The programmable AWR filter of claim 17, wherein each respective one of the plurality of shunt AWRs is turned on or off via respective switching components from among the second set of switching components to further adjust the filter response of the AWR filter by adjusting different notch locations in the filter response.

19. The programmable AWR filter of claim 15, wherein (i) each of the first AWRs and each of the second AWRs from among the plurality of resonator branches, and (ii) each of the plurality of shunt AWRs comprise a piezo micro-electromechanical system (MEMS) resonator having a first port and a second port.

20. The programmable AWR filter of claim 15, wherein each of the plurality of resonator branches and each of the plurality of shunt AWRs formed as part of a single integrated chip.
